(19) United States
(12) Patent Application Publication
(10) Pub. No.: US 2019/0229268 A1
(43) Pub. Date: Jul. 25, 2019

(54) CHARGE TRANSPORT MATERIAL, INK COMPOSITION AND ORGANIC ELECTRONIC ELEMENT

(71) Applicant: HITACHI CHEMICAL COMPANY, LTD., Tokyo (JP)

(72) Inventors: Kazuyuki KAMO, Chiyoda-ku, Tokyo (JP); Naoki ASANO, Chiyoda-ku, Tokyo (JP); Daisuke RYUZAKI, Chiyoda-ku, Tokyo (JP)

(21) Appl. No.: 16/327,105

(22) PCT Filed: Jul. 25, 2017
(86) PCT No.: PCT/JP2017/026860

§ 371 Date: Feb. 21, 2019

(30) Foreign Application Priority Data
Aug. 25, 2016 (JP) 2016-164723

(51) Int. Cl. H01L 51/00

(52) U.S. Cl. CPC H01L 51/0042; H01L 51/0035; H01L 51/5056; H01L 51/0005; H01L 51/005

(57) ABSTRACT

One embodiment relates to a charge transport material containing a proton donor and a hole transport polymer having a group represented by formula (Ia) shown below.

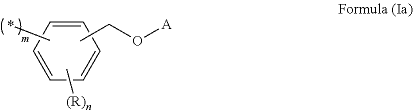

### TECHNICAL FIELD

The present disclosure relates to a charge transport material, an ink composition, an organic layer, an organic electronic element, an organic electroluminescent element (organic EL element), a display element, an illumination device and a display device, and also relates to methods for producing an organic layer, an organic electronic element and an organic electroluminescent element.

### BACKGROUND ART

Organic electronic elements are elements which use an organic substance to perform an electrical operation, and because they are expected to be capable of providing advantages such as low energy consumption, low prices and superior flexibility, they are attracting considerable attention as a potential alternative technology to conventional inorganic semiconductors containing mainly silicon.

Examples of organic electronic elements include organic EL elements, organic photoelectric conversion elements, and organic transistors and the like.

Among organic electronic elements, organic EL elements are attracting attention for potential use in large-surface area solid state lighting applications to replace incandescent lamps and gas-filled lamps and the like. Further, organic EL elements are also attracting attention as the leading self-luminous display for replacing liquid crystal displays (LCD) in the field of flat panel displays (FPD), and commercial products are becoming increasingly available.

Depending on the organic materials used, organic EL elements are broadly classified into two types: low-molecular weight type organic EL elements and polymer type organic EL elements. In polymer type organic EL elements, a polymer material is used as the organic material, whereas in low-molecular weight type organic EL elements, a low-molecular weight material is used. Compared with low-molecular weight type organic EL elements in which film formation is mainly performed in vacuum systems, polymer type organic EL elements enable simple film formation to be conducted by wet processes such as printing, and are therefore expected to be indispensable elements in future large-screen organic EL displays.

On the other hand, in organic EL elements, multilayering of the organic layers that form the element is used to improve element characteristics such as the lifespan and the emission efficiency. In a vapor deposition method, multilayering can be achieved easily by sequentially changing the compound being used as the vapor deposition is performed. However, in order to achieve multilayering of organic layers using wet processes, a method that ensures that the lower layer does not dissolve during formation of the upper layer is required. Accordingly, compounds having a polymerizable group are being investigated for use as the material for forming the lower layer (for example, see Patent Literature 1).

### CITATION LIST

### Patent Literature

PLT 1: JP 2006-279007 A

### SUMMARY OF INVENTION

### Technical Problem

The present disclosure provides a charge transport material and an ink composition that enable multilayering of organic layers using wet processes to be achieved with ease, and also provides an organic layer that is formed using the charge transport material or the ink composition. Further, the present disclosure also provides an organic electronic element and an organic EL element having organic layers with excellent solvent resistance, and a display element, an illumination device and a display device that use these elements. Moreover, the present disclosure also provides simple methods for producing the organic layer, the organic electronic element and the organic EL element.

### Solution to Problem

Examples of embodiments of the invention are described below. However, the present invention is not limited to the following embodiments.

One embodiment relates to a charge transport material containing a proton donor and a hole transport polymer having a group represented by formula (Ia) shown below.

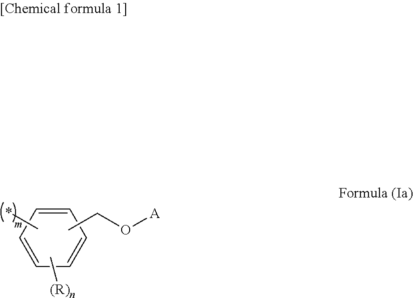

(In formula (Ia), A represents a monovalent organic group, R represents a monovalent substituent, m represents an integer of 1 to 3, n represents an integer of 0 to 4, and m+n is 5 or less.)

In one preferred embodiment, the group represented by formula (Ia) includes a group represented by formula (Ib) shown below.

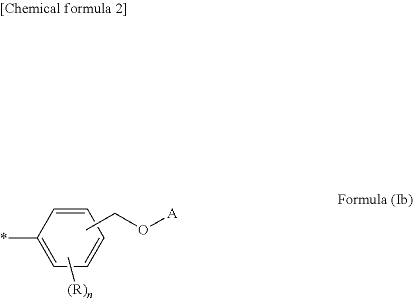

(In formula (Ib), A represents a monovalent organic group, R represents a monovalent substituent, and n represents an integer of 0 to 4.)

In one preferred embodiment, the proton donor includes a compound represented by formula (II) shown below.

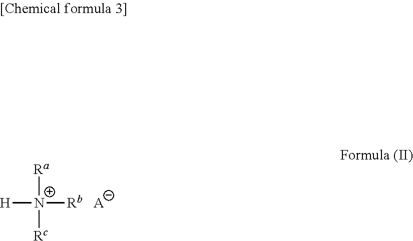

(In formula (II):

each of R^{a} to R^{c} independently represents a hydrogen atom, an alkyl group, an arylalkyl group, an aryl group or a heteroaryl group, and at least two groups selected from among R^{a} to R^{c} may be bonded together to form a ring, and

A represents an anion.)

In one preferred embodiment, the hole transport polymer has a branched structure.

In one preferred embodiment, the hole transport polymer has at least one type of structure selected from the group consisting of aromatic amine structures and carbazole structures.

Further, in one preferred embodiment, the hole transport polymer has the group represented by formula (Ia) at least at one terminal.

Another embodiment relates to an ink composition containing one of the charge transport materials described above and a solvent.

Another embodiment relates to an organic layer formed using one of the charge transport materials described above.

Further, other embodiments relate to an organic electronic element having the above organic layer; and an organic electroluminescent element having the above organic layer.

Furthermore, other embodiments relate to a display element containing the above organic electroluminescent element; an illumination device containing the above organic electroluminescent element; and a display device containing the above illumination device and a liquid crystal element as a display unit.

Moreover, other embodiments relate to a method for producing an organic layer that includes a step of applying the ink composition described above to form a coating layer, and a step of subjecting the coating layer to at least one type of treatment selected from the group consisting of heating treatments and light irradiation treatments; a method for producing an organic electronic element that includes a step of applying the ink composition described above to form a coating layer, and a step of forming an organic layer by subjecting the coating layer to at least one type of treatment selected from the group consisting of heating treatments and light irradiation treatments; and a method for producing an organic electroluminescent element that includes a step of applying the ink composition described above to form a coating layer, and a step of forming an organic layer by subjecting the coating layer to at least one type of treatment selected from the group consisting of heating treatments and light irradiation treatments.

The present invention is related to the subject matter disclosed in Japanese Application 2016-164723 filed on Aug. 25, 2016, the entire contents of which are incorporated by reference herein.

### Advantageous Effects of Invention

The present disclosure provides a charge transport material and an ink composition that enable multilayering of organic layers using wet processes to be achieved with ease, and also provides an organic layer that is formed using the charge transport material or the ink composition. Further, the present disclosure also provides an organic electronic element and an organic EL element having organic layers with excellent solvent resistance, and a display element, an illumination device and a display device that use these elements. Moreover, the present disclosure also provides simple methods for producing the organic layer, the organic electronic element and the organic EL element.

### BRIEF DESCRIPTION OF DRAWINGS

FIG. 1 is a cross-sectional schematic view illustrating one example of an organic EL element of one embodiment.

### DESCRIPTION OF EMBODIMENTS

Embodiments of the present invention are described below. However, the present invention is not limited by the following embodiments.

As a result of intensive investigation, the inventors of the present invention discovered that by using a charge transport material containing a proton donor and a hole transport polymer having an oxymethylene group bonded to a benzene ring (a benzyl ether linkage), and changing the degree of solubility of the hole transport polymer, the solvent resistance of an organic layer could be improved, and they were therefore able to complete the present invention including various embodiments.

### <Charge Transport Material>

According to one embodiment, a charge transport material contains a proton donor and a hole transport polymer having a group represented by formula (Ia) (hereafter sometimes referred to as simply “the hole transport polymer”). The charge transport material may contain only one type of hole transport polymer, or may contain two or more types. Further, the charge transport material may contain only one type of proton donor, or may contain two or more types.

### [Hole Transport Polymer]

The hole transport polymer has a group represented by formula (Ia) shown below. By subjecting the hole transport polymer to a heating treatment and/or a light irradiation treatment in the presence of the proton donor, the degree of solubility of the hole transport polymer in organic solvents can be changed.

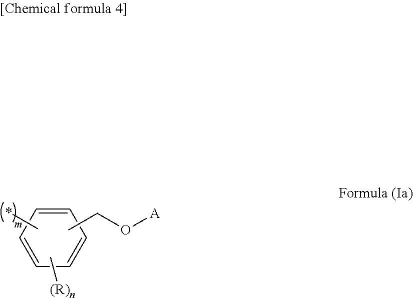

In formula (Ia), A represents a monovalent organic group, R represents a monovalent substituent, m represents an integer of 1 to 3, n represents an integer of 0 to 4, and m+n is 5 or less. The symbol “*” indicates a bonding site with another structure, and m represents the number of these bonding sites. Further, n represents the number of R groups. It is preferable that each R independently represents a monovalent substituent, and in those cases where a plurality of R groups exist, the plurality of R groups may be the same or different.

The hole transport polymer preferably has a group represented by formula (Ib) shown below. By including a group represented by formula (Ib) in the hole transport polymer, the degree of solubility of the hole transport polymer in organic solvents can be changed efficiently. Further, having the group represented by formula (Ib) at a terminal of the hole transport polymer is preferred from the viewpoint of ease of synthesis. The group represented by formula (Ib) is an example of a group of the formula (Ia) in which m is 1.

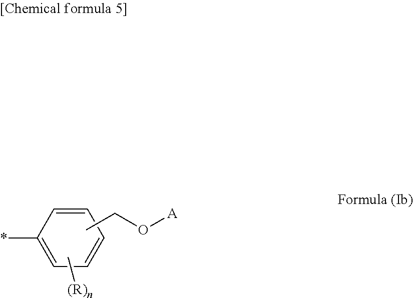

In formula (Ib), A represents a monovalent organic group, R represents a monovalent substituent, and n represents an integer of 0 to 4. The symbol “*” indicates a bonding site with another structure. Further, n represents the number of R groups. It is preferable that each R independently represents a monovalent substituent, and in those cases where a plurality of R groups exist, the plurality of R groups may be the same or different.

### (Group Represented by Formula (Ia))

In the group represented by formula (Ia), A represents an organic group. Examples of the organic group include substituted or unsubstituted aliphatic hydrocarbon groups, substituted or unsubstituted aromatic hydrocarbon groups, and hydrocarbon groups containing aliphatic and aromatic groups bonded together.

The number of carbon atoms in the aliphatic hydrocarbon group (excluding any carbon atoms contained in substituents) may be 1 or greater, and from the viewpoint of improving the solubility in organic solvents, is preferably at least 2, more preferably at least 3, and even more preferably 4 or greater. Further, from the viewpoint of enabling the material used for introducing the group represented by formula (Ia) to be procured or synthesized easily, the number of carbon atoms in the aliphatic hydrocarbon group (excluding any carbon atoms contained in substituents) is preferably not more than 22, more preferably not more than 12, and even more preferably 8 or fewer. The aliphatic hydrocarbon group may be linear, branched or cyclic. Examples of the aliphatic hydrocarbon group include alkyl groups, alkenyl groups and alkenyl groups, and alkyl groups are preferred. Specific examples of these alkyl groups include a methyl group, ethyl group, propyl group, i-propyl group, butyl group, i-butyl group, t-butyl group, pentyl group, hexyl group, cyclohexyl group, heptyl group, octyl group, 2-ethylhexyl group, nonyl group, 3,7-dimethyloctyl group, decyl group, undecyl group, dodecyl group, tridecyl group, tetradecyl group, pentadecyl group, hexadecyl group, heptadecyl group, octadecyl group, nonadecyl group, icosyl group and eicosyl group.

The number of carbon atoms in the aromatic hydrocarbon group (excluding any carbon atoms contained in substituents) may be 6 or greater. From the viewpoint of improving the solubility in organic solvents, the number of carbon atoms in the aromatic hydrocarbon group (excluding any carbon atoms contained in substituents) is preferably not more than 30, more preferably not more than 14, and even more preferably 10 or fewer. Examples of the aromatic hydrocarbon group include aryl groups, and specific examples of these aryl groups include a phenyl group, naphthyl group, anthracenyl group, tetracenyl group, pentacenyl group, phenanthrenyl group, chrysenyl group, triphenylenyl group, tetraphenyl group, pyrenyl group, picenyl group, pentaphenyl group, perylenyl group and pentahelicenyl group.

In a hydrocarbon group containing a substituted or unsubstituted aliphatic hydrocarbon group and a substituted or unsubstituted aromatic hydrocarbon group bonded together, the “aliphatic hydrocarbon group” and the “aromatic hydrocarbon group” are as described above. The number of carbon atoms in this hydrocarbon group (excluding any carbon atoms contained in substituents) may be 7 or greater. From the viewpoint of improving the solubility in organic solvents, the number of carbon atoms in the hydrocarbon group (excluding any carbon atoms contained in substituents) is preferably not more than 30, more preferably not more than 14, and even more preferably 10 or fewer. Examples of this hydrocarbon group include arylalkyl groups and alkylaryl groups. Specific examples of the arylalkyl groups include a benzyl group, phenethyl group, naphthylmethyl group, naphthylethyl group and diphenylmethyl group. Specific examples of the alkylaryl groups include a tolyl group, ethylphenyl group, methylnaphthyl group, ethylnaphthyl group, and xylyl group.

R represents a monovalent organic group, and examples include groups described below including —R¹ (but excluding the case of a hydrogen atom), —OR², —OCOR⁴, —COOR⁵, —SiR⁶R⁷R⁸ and halogen atoms. Further, n is an integer of 0 to 4, and is preferably 0 or 1. When n is an integer of 2 to 4, the R groups may be the same or different.

When the hole transport polymer is subjected to a heating treatment and/or light irradiation treatment in the presence of the proton donor, it is thought that the group represented by formula (Ia) undergoes cleavage of the oxymethylene group and elimination of the A-O— group, thereby changing the affinity of the polymer relative to organic solvents. The reaction formula is shown below, using as an example the case where m is 1 and n is 0 in the group represented by formula (Ia). It is surmised that the change in the degree of solubility of the hole transport polymer occurs due to the elimination of a portion of the group represented by formula (Ia). In the following description, the eliminated A-O— group is sometimes referred to as “the atom grouping A”.

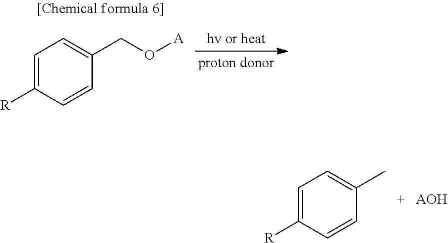

R in the above reaction formula represents the polymer chain of the hole transport polymer.

For example, in those cases where the group represented by formula (Ia) has an atom grouping (A) that exhibits high affinity with organic solvents, the hole transport polymer will exist in a state having a high degree of solubility in organic solvents. When the atom grouping (A) is eliminated from the group represented by formula (Ia), the degree of solubility of the hole transport polymer in organic solvents changes to a state of low solubility.

By utilizing this change, the charge transport material containing the hole transport polymer can, for example, be used favorably as an organic electronic material. Specifically, by dissolving the hole transport polymer having the group represented by formula (Ia) in an organic solvent, a coating layer can be formed using a coating method. Subsequently, by eliminating the atom grouping (A) from the hole transport polymer, the degree of solubility of the hole transport polymer in organic solvents can be lowered. As a result, an organic layer containing a hole transport polymer having a low degree of solubility in organic solvents is obtained. When the thus obtained organic layer is used as a lower layer, and an upper layer is formed on the lower layer by a coating method, dissolution of the lower layer in the organic solvent is suppressed, and the upper layer can be formed favorably. By using the hole transport polymer having a group represented by formula (Ia), multilayering of organic layers by wet processes becomes simple.

In order to facilitate reaction with the proton donor described below, the group represented by formula (Ia) is preferably introduced at least at one or more terminals of the hole transport polymer. A terminal describes the end of a polymer chain.

There are no particular limitations on the number of groups represented by formula (Ia) contained within a single molecule of the hole transport polymer. However, in order to achieve a favorable change in the degree of solubility, the number of groups is preferably at least two, and more preferably three or greater. Further, from the viewpoint of maintaining satisfactory hole transport properties, the number of groups per molecule is preferably not more than 1,000, and more preferably 500 or fewer.

From the viewpoint of achieving a favorable change in the degree of solubility of the hole transport polymer, the proportion of the group represented by formula (Ia) within the hole transport polymer, based on the total of all the structural units, is preferably at least 5 mol %, more preferably at least 10 mol %, and even more preferably 15 mol % or greater. From the viewpoint of limiting the reduction in film thickness, the proportion of the group represented by formula (Ia) within the hole transport polymer is preferably not more than 95 mol %, more preferably not more than 90 mol %, and even more preferably 85 mol % or less. Here, the “proportion of the group represented by formula (Ia)” means the proportion of the structural unit having the group represented by formula (Ia).

### (Structure of Hole Transport Polymer)

The hole transport polymer may be linear, or may have a branched structure. A linear hole transport polymer has two terminals, whereas a hole transport polymer having a branched structure has three or more terminals. A terminal describes an end of a polymer chain. From the viewpoint of efficiently changing the degree of solubility of the hole transport polymer, and from the viewpoint of improving the lifespan of the organic electronic element, the hole transport polymer preferably has a branched structure.

The hole transport polymer preferably includes a structural unit that has the ability to transport positive holes (sometimes called a “structural unit having hole transport properties”). The hole transport polymer may be a polymer that has only one type of structural unit, or may be a polymer having two or more types of structural units. In those cases where the hole transport polymer is a copolymer, the copolymer may be an alternating, random, block or graft copolymer, or may be a copolymer having an intermediate type structure, such as a random copolymer having block-like properties. In one embodiment, a structural unit means a monomer unit.

For example, the hole transport polymer may contain at least a divalent structural unit L having hole transport properties and a monovalent structural unit T that forms the terminal portions, and may also have a trivalent or higher structural unit B that forms a branch portion. In other words, the hole transport polymer has at least the structural unit L as a “structural unit having hole transport properties”, but the structural unit T and/or the structural unit B may also be a structural unit having hole transport properties. Further, in another example, the hole transport polymer may contain at least a trivalent structural unit B having hole transport properties and a monovalent structural unit T that forms the terminal portions, and may also have an optional divalent structural unit L. In other words, the hole transport polymer has at least the structural unit B as the “structural unit having hole transport properties”, but the structural unit T and/or the structural unit L may also be a structural unit having hole transport properties. The hole transport polymer may contain only one type of each of these structural units, or may contain a plurality of types of each structural unit. In the hole transport polymer, the various structural units are bonded together at “monovalent” to “trivalent or higher” bonding sites.

The group represented by formula (Ia) may be included in at least one type of the structural unit L, the structural unit T or the structural unit B. From the viewpoint of efficiently changing the degree of solubility of the hole transport polymer, it is preferable that the structural unit T has the group represented by formula (Ia).

Examples of partial structures contained in the hole transport polymer are described below. However, the hole transport polymer is not limited to polymers having the following partial structures. In the partial structures, “L” represents a structural unit L, “T” represents a structural unit T, and “B” represents a structural unit B. The symbol “*” indicates a bonding site with another structural unit. In the following partial structures, the plurality of L structural units may be structural units having the same structure or structural units having mutually different structures. This also applies for the T and B structural units.

### Linear Hole Transport Polymers

T-L-L-L-L-L-* [Chemical formula 7]

### Hole Transport Polymers Having a Branched Structure

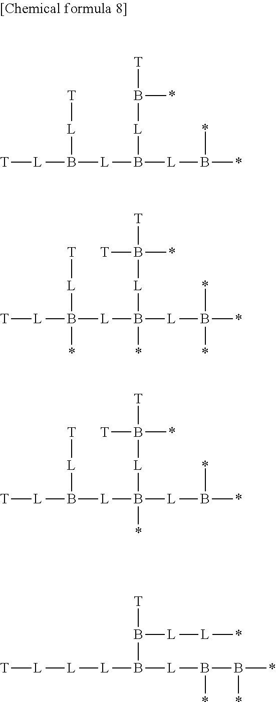

### (Structural Unit L)

The structural unit L is preferably a divalent structural unit having hole transport properties. There are no particular limitations on preferred structural units L, provided the structural unit includes an atom grouping having the ability to transport a positive hole. For example, the structural unit L may be selected from among aromatic amine structures, carbazole structures, thiophene structures, fluorene structures, benzene structures, biphenyl structures, terphenyl structures, naphthalene structures, anthracene structures, tetracene structures, phenanthrene structures, dihydrophenanthrene structures, pyridine structures, pyrazine structures, quinoline structures, isoquinoline structures, quinoxaline structures, acridine structures, diazaphenanthrene structures, furan structures, pyrrole structures, oxazole structures, oxadiazole structures, thiazole structures, thiadiazole structures, triazole structures, benzothiophene structures, benzoxazole structures, benzoxadiazole structures, benzothiazole structures, benzothiadiazole structures, and benzotriazole structures, which may be substituted or unsubstituted, and structures containing one type, or two or more types, of the above structures. The aromatic amine structures are preferably triarylamine structures, and more preferably triphenylamine structures.

In one embodiment, from the viewpoint of obtaining superior hole transport properties, the structural unit L is preferably selected from among aromatic amine structures, carbazole structures, thiophene structures, fluorene structures, and benzene structures, which may be substituted or unsubstituted, and structures containing one type, or two or more types, of these structures, and is more preferably selected from among substituted or unsubstituted aromatic amine structures, substituted or unsubstituted carbazole structures, and structures containing one type, or two or more types, of these structures.

Specific examples of the structural unit L are shown below. However, the structural unit L is not limited to the following structures.

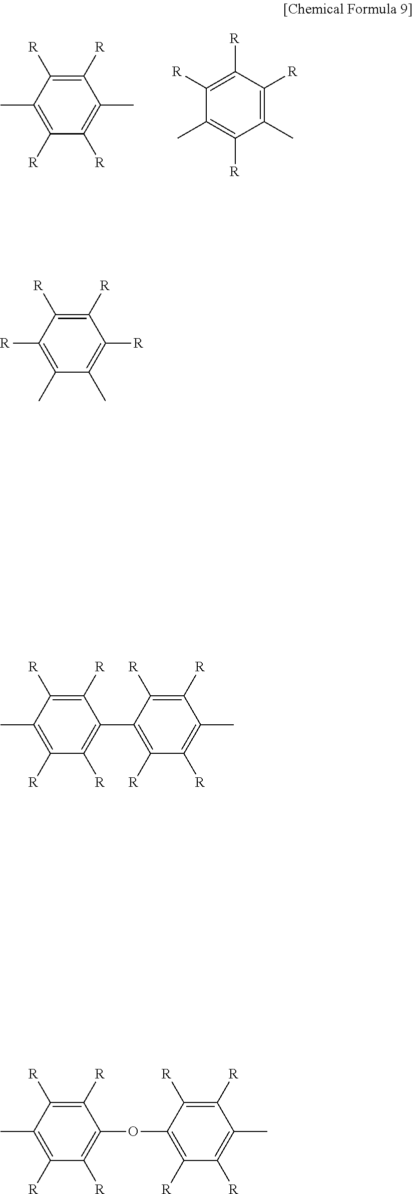

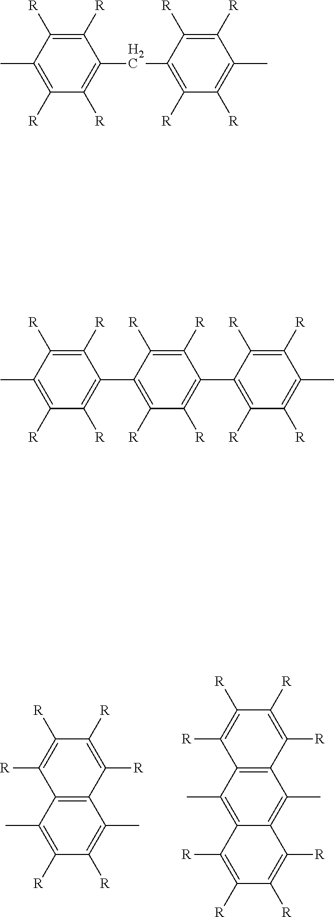

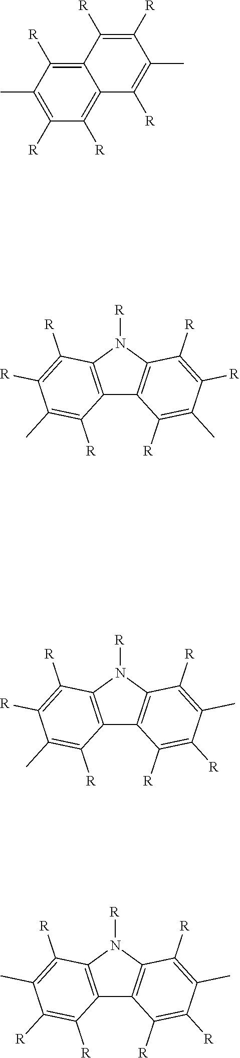

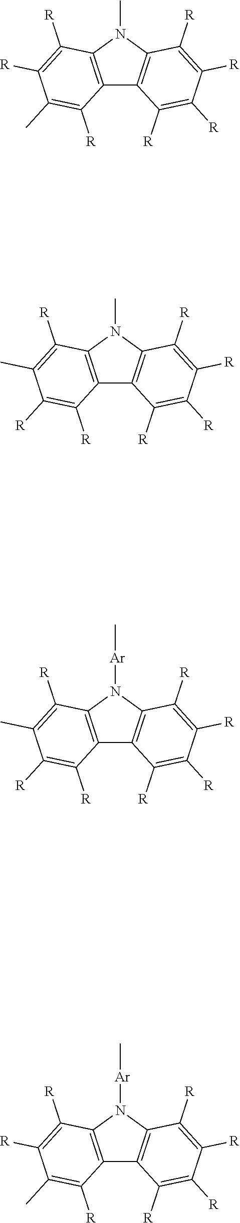

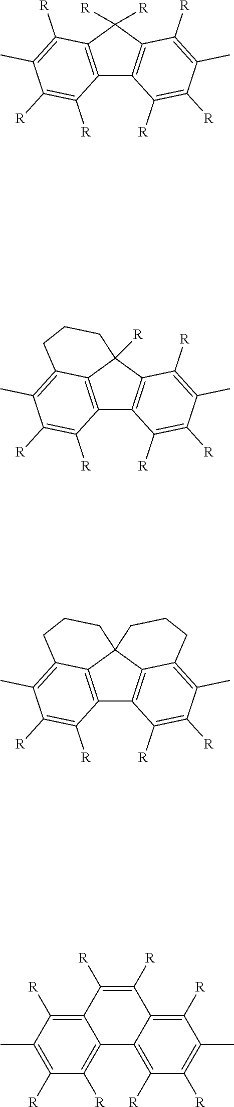

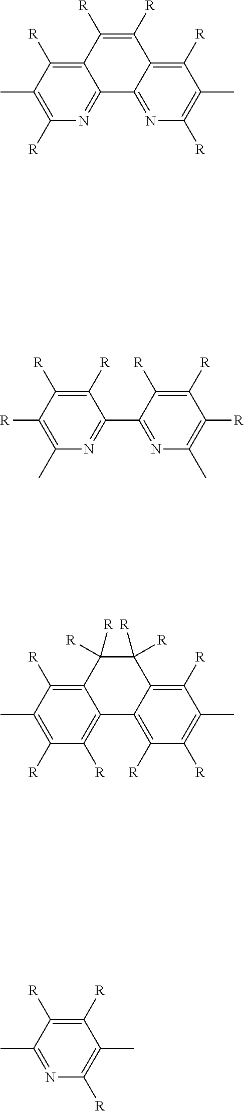

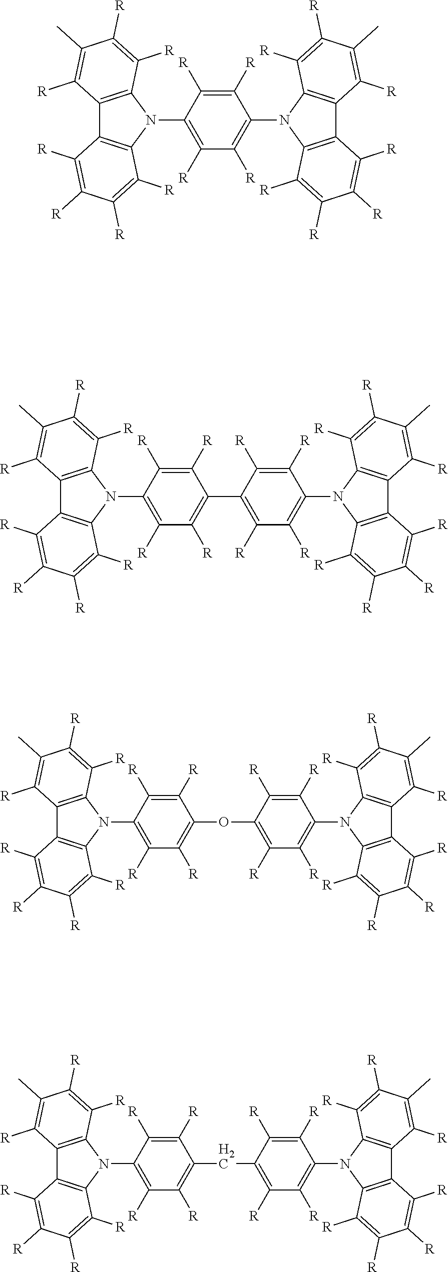

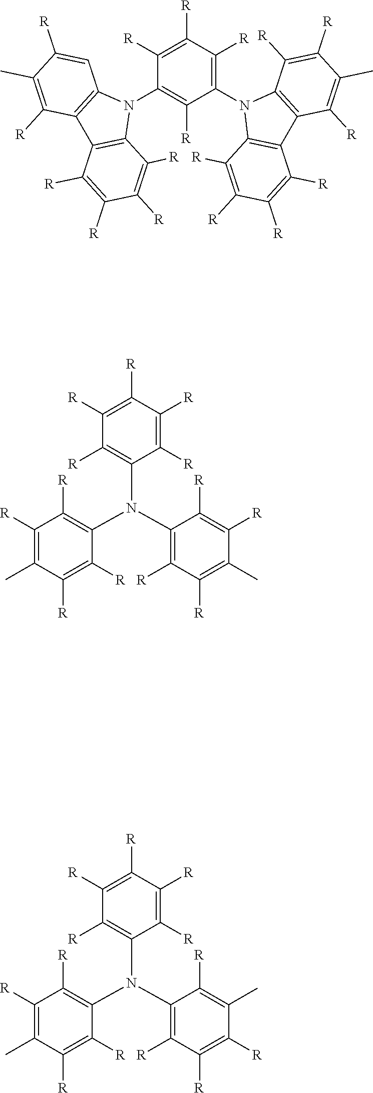

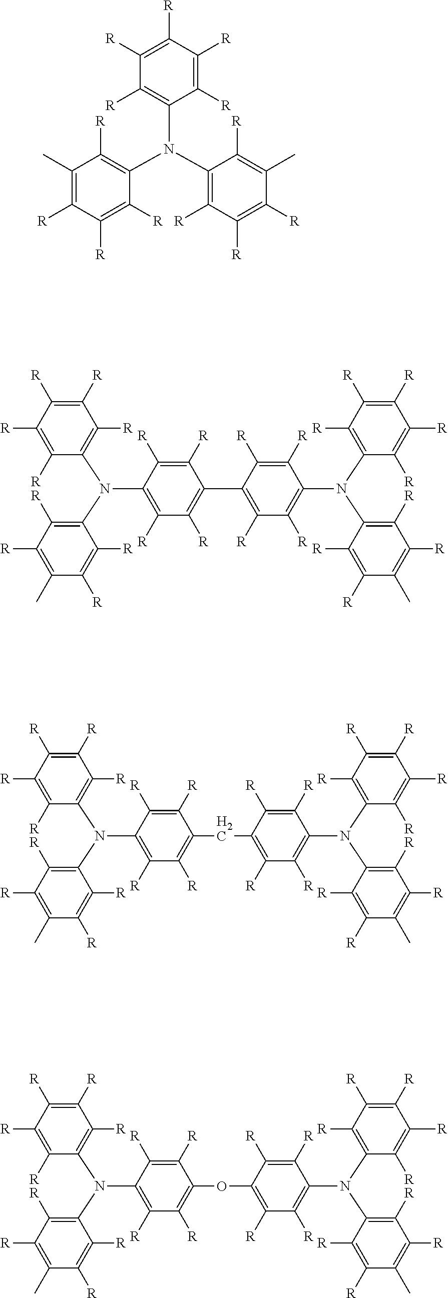

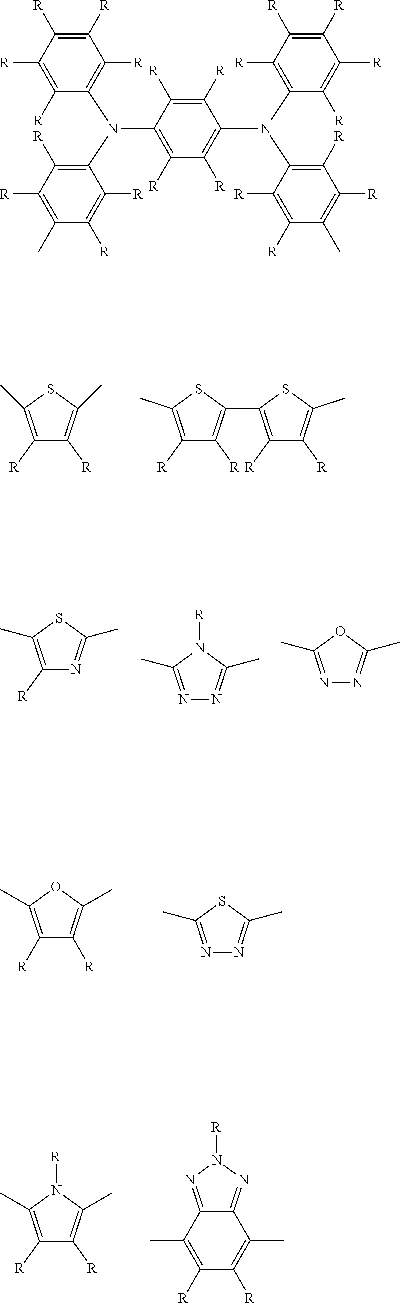

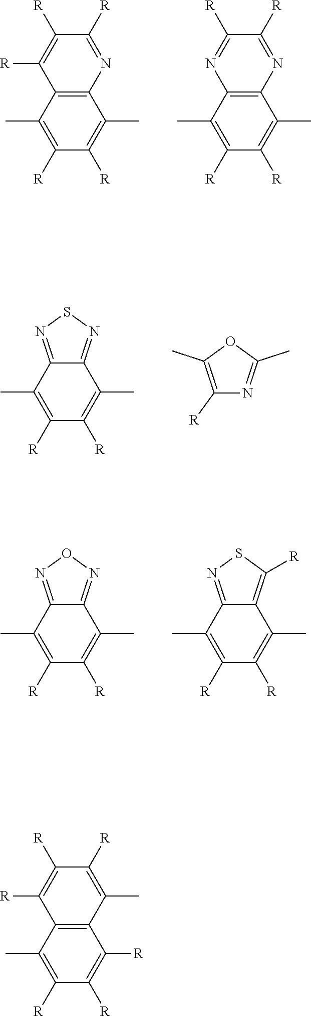

Each R independently represents a hydrogen atom or a substituent. It is preferable that each R is independently selected from a group consisting of —R¹, —OR², —SR³, —OCOR⁴, —COOR⁵, —SiR⁶R⁷R⁸, halogen atoms, groups represented by formula (Ib) shown above, and groups represented by formula (Ic) shown below. Each of R¹ to R⁸ independently represents a hydrogen atom; a linear, cyclic or branched alkyl group of 1 to 22 carbon atoms; or an aryl group or heteroaryl group of 2 to 30 carbon atoms. An aryl group is an atom grouping in which one hydrogen atom has been removed from an aromatic hydrocarbon. A heteroaryl group is an atom grouping in which one hydrogen atom has been removed from an aromatic heterocycle. The alkyl group may be further substituted with an aryl group or heteroaryl group of 2 to 20 carbon atoms, and the aryl group or heteroaryl group may be further substituted with a linear, cyclic or branched alkyl group of 1 to 22 carbon atoms. R is preferably a hydrogen atom, an alkyl group, an aryl group, or an alkyl-substituted aryl group. Ar represents an arylene group or heteroarylene group of 2 to 30 carbon atoms. An arylene group is an atom grouping in which two hydrogen atoms have been removed from an aromatic hydrocarbon. A heteroarylene group is an atom grouping in which two hydrogen atoms have been removed from an aromatic heterocycle. Ar is preferably an arylene group, and is more preferably a phenylene group.

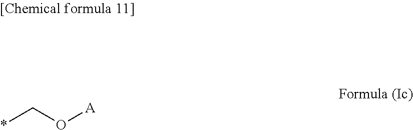

A represents the same as A in the group represented by formula (Ia).

Examples of the aromatic hydrocarbon include monocyclic rings, condensed rings, and polycyclic rings in which two or more rings selected from among monocyclic rings and condensed rings are bonded together via single bonds. Examples of the aromatic heterocycles include monocyclic rings, condensed rings, and polycyclic rings in which two or more rings selected from among monocyclic rings and condensed rings are bonded together via single bonds. This description also applies to the arenetriyl groups and heteroarenetriyl groups described below.

### (Structural Unit T)

The structural unit T is a monovalent structural unit that forms a terminal portion of the hole transport polymer. There are no particular limitations on the structural unit T, which may, for example, be selected from among substituted or unsubstituted aromatic hydrocarbon structures, substituted or unsubstituted aromatic heterocyclic structures, and structures containing one type, or two or more types, of these structures. The structural unit T may have a similar structure to the structural unit L. In one embodiment, from the viewpoint of imparting durability without impairing the charge transport properties, the structural unit T is preferably a substituted or unsubstituted aromatic hydrocarbon structure, and is more preferably a substituted or unsubstituted benzene structure.

A specific example of the structural unit T is shown below. However, the structural unit T is not limited to the following structure.

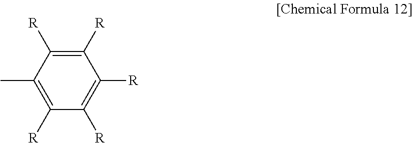

R is the same as R in the structural unit L. In those cases where the hole transport polymer has a group represented by formula (Ia) at a terminal portion, it is preferable that at least one R group is either a group represented by formula (Ib) shown above or a group represented by formula (Ic) shown above.

### (Structural Unit B)

The structural unit B is a trivalent or higher structural unit that forms a branched portion in those cases where the hole transport polymer has a branched structure. From the viewpoint of improving the durability of the organic electronic element, the structural unit B is preferably not higher than hexavalent, and is more preferably either trivalent or tetravalent. The structural unit B is preferably a unit that has hole transport properties. For example, from the viewpoint of improving the durability of the organic electronic element, the structural unit B is preferably selected from among aromatic amine structures, carbazole structures, and condensed polycyclic aromatic hydrocarbon structures, which may be substituted or unsubstituted, and structures containing one type, or two or more types, of these structures.

Specific examples of the structural unit B are shown below. However, the structural unit B is not limited to the following structures.

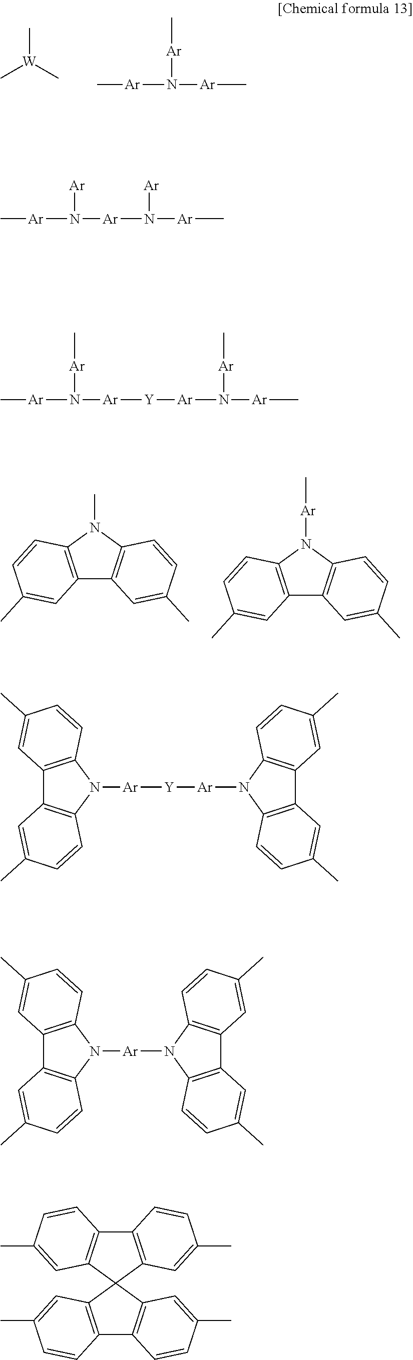

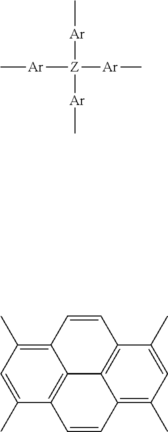

W represents a trivalent linking group, and for example, represents an arenetriyl group or heteroarenetriyl group of 2 to 30 carbon atoms. An arenetriyl group is an atom grouping in which three hydrogen atoms have been removed from an aromatic hydrocarbon. A heteroarenetriyl group is an atom grouping in which three hydrogen atoms have been removed from an aromatic heterocycle. Each Ar independently represents a divalent linking group, and for example, may represent an arylene group or heteroarylene group of 2 to 30 carbon atoms. Ar is preferably an arylene group, and more preferably a phenylene group. Y represents a divalent linking group, and examples include divalent groups in which an additional hydrogen atom has been removed from any of the R groups having one or more hydrogen atoms (but excluding groups represented by formula (Ib) and groups represented by formula (Ic)) described in relation to the structural unit L. Z represents a carbon atom, a silicon atom or a phosphorus atom. In the above structural units, the benzene rings and Ar groups may have substituents, and examples of the substituents include the R groups in the structural unit L.

### (Number Average Molecular Weight)

The number average molecular weight of the hole transport polymer can be adjusted appropriately with due consideration of the solubility in solvents and the film formability and the like. From the viewpoint of ensuring superior hole transport properties, the number average molecular weight is preferably at least 500, more preferably at least 1,000, and even more preferably 2,000 or greater. From the viewpoints of maintaining favorable solubility in solvents and facilitating the preparation of ink compositions, the number average molecular weight is preferably not more than 1,000,000, more preferably not more than 100,000, and even more preferably 50,000 or less.

### (Weight Average Molecular Weight)

The weight average molecular weight of the hole transport polymer can be adjusted appropriately with due consideration of the solubility in solvents and the film formability and the like. From the viewpoint of ensuring superior hole transport properties, the weight average molecular weight is preferably at least 1,000, more preferably at least 5,000, and even more preferably 10,000 or greater. From the viewpoints of maintaining favorable solubility in solvents and facilitating the preparation of ink compositions, the weight average molecular weight is preferably not more than 1,000,000, more preferably not more than 700,000, and even more preferably 400,000 or less.

The number average molecular weight and the weight average molecular weight can be measured by gel permeation chromatography (GPC), using a calibration curve of standard polystyrenes.

### (Proportions of Structural Units)

In those cases where the hole transport polymer includes a structural unit L, from the viewpoint of ensuring satisfactory hole transport properties, the proportion of the structural unit L, based on the total of all the structural units, is preferably at least 10 mol %, more preferably at least 20 mol %, and even more preferably 30 mol % or higher. If the structural unit T and the optionally introduced structural unit B are also taken into consideration, then the proportion of the structural unit L is preferably not more than 95 mol %, more preferably not more than 90 mol %, and even more preferably 85 mol % or less.

From the viewpoint of improving the characteristics of the organic electronic element, and from the viewpoint of suppressing any increase in viscosity and enabling more favorable synthesis of the hole transport polymer, the proportion of the structural unit T contained in the hole transport polymer, based on the total of all the structural units, is preferably at least 5 mol %, more preferably at least 10 mol %, and even more preferably 15 mol % or higher. From the viewpoint of obtaining satisfactory hole transport properties, the proportion of the structural unit T is preferably not more than 60 mol %, more preferably not more than 55 mol %, and even more preferably 50 mol % or less.

In those cases where the hole transport polymer has a group represented by formula (Ia) at one or more terminals, from the viewpoint of ensuring a satisfactory change in the degree of solubility, the proportion of structural units having a group represented by formula (Ia) among all of the terminals of the hole transport polymer, based on the total number of terminals, is preferably at least 25 mol %, more preferably at least 30 mol %, and even more preferably 35 mol % or greater. There are no particular limitations on the upper limit, and the proportion may be 100 mol % or less.

In those cases where the hole transport polymer includes a structural unit B, from the viewpoint of improving the durability of the organic electronic element, the proportion of the structural unit B, based on the total of all the structural units, is preferably at least 1 mol %, more preferably at least 5 mol %, and even more preferably 10 mol % or higher. From the viewpoints of suppressing any increase in viscosity and enabling more favorable synthesis of the hole transport polymer, and from the viewpoint of ensuring satisfactory hole transport properties, the proportion of the structural unit B is preferably not more than 50 mol %, more preferably not more than 40 mol %, and even more preferably 30 mol % or less.

Considering the balance between the hole transport properties, durability and productivity and the like, in those cases where the hole transport polymer contains a structural unit L and a structural unit T, the ratio (molar ratio) between the structural unit L and the structural unit T is preferably L:T=100:(1 to 70), more preferably 100:(3 to 50), and even more preferably 100:(5 to 30). Further, in those cases where the charge transport polymer also contains a structural unit B, the ratio (molar ratio) between the structural unit L, the structural unit T and the structural unit B is preferably L:T:B=100:(10 to 200):(10 to 100), more preferably 100:(20 to 180):(20 to 90), and even more preferably 100:(40 to 160):(30 to 80).

The proportion of each structural unit can be determined using the amount added of the monomer corresponding with that structural unit during synthesis of the hole transport polymer. Further, the proportion of each structural unit can also be calculated as an average value using the integral of the spectrum attributable to the structural unit in the ¹H-NMR spectrum of the hole transport polymer. In terms of ease of calculation, if the amounts added are clear, then the proportion of the structural unit preferably employs the value determined using the amount added of the corresponding monomer.

### (Method for Producing Hole Transport Polymer)

The hole transport polymer can be produced by various synthesis methods, and there are no particular limitations. For example, conventional coupling reactions such as the Suzuki coupling, Negishi coupling, Sonogashira coupling, Stille coupling and Buchwald-Hartwig coupling reactions can be used. The Suzuki coupling is a reaction in which a cross-coupling reaction is initiated between an aromatic boronic acid derivative and an aromatic halogen compound using a Pd catalyst. By using a Suzuki coupling, the hole transport polymer can be produced easily by bonding together the desired aromatic rings.

In the coupling reaction, a Pd(0) compound, Pd(II) compound, or Ni compound or the like is used as a catalyst. Further, a catalyst species generated by mixing a precursor such as tris(dibenzylideneacetone)dipalladium(0) or palladium(II) acetate with a phosphine ligand can also be used. Reference may also be made to WO 2010/140553 in relation to synthesis methods for the hole transport polymer.

### [Proton Donor]

The proton donor is a compound that can donate a proton to the charge transport polymer. It is thought that the group represented by formula (Ia) accepts the donated proton from the proton donor, resulting in cleavage of the oxymethylene group. Examples of the proton donor include organic acids such as carboxylic acids and sulfonic acids, inorganic acids, and onium salts and the like. From the viewpoint of the solubility in organic solvents, onium salts are preferred.

A compound having at least one proton that can be donated to the charge transport polymer is used as the onium salt. Examples of the onium salt include phosphonium salts, oxonium salts, sulfonium salts and ammonium salts. From the viewpoint of improving the conductivity, ammonium salts are preferred.

An ammonium salt contains a nitrogen cation. Examples of the nitrogen cation include NH₄⁺, primary nitrogen cations, secondary nitrogen cations, and tertiary nitrogen cations.

A compound represented by formula (II) shown below may be used as the ammonium salt.

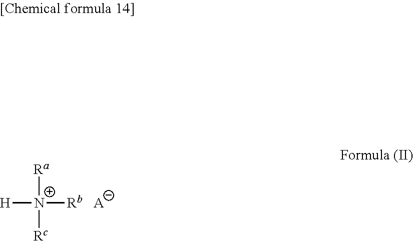

Each of R^{a} to R^{c} independently represents a hydrogen atom, an alkyl group, an arylalkyl group, an aryl group or a heteroaryl group, and at least two groups selected from among R^{a} to R^{c} may be bonded together to form a ring.

A represents an anion.

It is thought that the compound represented by formula (II) has two functions in the charge transport material: a function of cleaving the oxymethylene group contained in the hole transport polymer, and a doping function relative to the hole transport polymer.

From the viewpoint of improving the solubility in organic solvents, at least one of R^{a} to R^{c} is preferably an alkyl group or an arylalkyl group, and is more preferably an alkyl group. It is more preferable that all of R^{a} to R^{c} are alkyl groups or arylalkyl groups, and it is particularly preferable that all of R^{a} to R^{c} are alkyl groups. In other words, it is preferable that not all of R^{a} to R^{c} are aryl groups and/or heteroaryl groups.

The alkyl group may be linear, branched or cyclic, may have a substituent, and preferably has 1 to 24 carbon atoms, more preferably 1 to 20 carbon atoms, and even more preferably 1 to 18 carbon atoms. Specific examples include a methyl group, ethyl group, propyl group, i-propyl group, butyl group, i-butyl group, t-butyl group, pentyl group, hexyl group, cyclohexyl group, heptyl group, octyl group, 2-ethylhexyl group, nonyl group, decyl group, dodecyl group, tetradecyl group, octadecyl group, 3,7-dimethyloctyl group, lauryl group, trifluoromethyl group, pentafluoroethyl group, perfluorobutyl group, perfluorohexyl group, and perfluorooctyl group.

From the viewpoint of improving the solubility in organic solvents, it is preferable that at least one of R^{a} to R^{c} is an alkyl group of at least 7 carbon atoms, and at least one other of R^{a} to R^{c} is an alkyl group of not more than 6 carbon atoms; and it is more preferable that one of R^{a} to R^{c} is an alkyl group of at least 7 carbon atoms, and the other two of R^{a} to R^{c} are alkyl groups of not more than 6 carbon atoms.

The aryl group may have a substituent. The number of carbon atoms in the monovalent aryl group in an unsubstituted state is preferably from 6 to 60, and more preferably from 6 to 18. Specific examples include a phenyl group, C1 to C12 alkoxy-phenyl groups (here C1 to C12 means that the number of carbon atoms in the substituent is from 1 to 12, this numbering system also applies below), C1 to C12 alkyl-phenyl groups, and a 1-naphthyl group, 2-naphthyl group, 1-anthracenyl group, 2-anthracenyl group, 9-anthracenyl group, phenanthrenyl group, pyrenyl group, perylenyl group and pentafluorophenyl group, and of these, a C1 to C12 alkoxy-phenyl group or a C1 to C12 alkyl-phenyl group is preferred.

The heteroaryl group may have a substituent. The number of carbon atoms in the monovalent heteroaryl group in an unsubstituted state is preferably from 4 to 60, and more preferably from 4 to 20. Specific examples include a thienyl group, C1 to C12 alkyl-thienyl groups, pyrrolyl group, furyl group, pyridyl group and C1 to C12 alkyl-pyridyl groups, and of these, a thienyl group, C1 to C12 alkyl-thienyl group, pyridyl group or C1 to C12 alkyl-pyridyl group is preferred. The meaning of C1 to C12 is as described above.

The arylalkyl group is a group in which at least one hydrogen atom of an alkyl group has been substituted with an aryl group. The arylalkyl group may also have a substituent. The number of carbon atoms in the monovalent arylalkyl group in an unsubstituted state is preferably from 7 to 19, and more preferably from 7 to 13. Examples of the alkyl group include the alkyl groups mentioned above, and examples of the aryl group include the aryl groups mentioned above. Specific examples of the arylalkyl group include a benzyl group, phenethyl group, naphthylmethyl group, naphthylethyl group and diphenylmethyl group.

A represents an anion, and examples include halogen ions, a hydroxide ion, sulfonate ion, sulfate ion, carbonate ion, phosphate ion, borate ion, and anions selected from the group consisting of anions of formulas (1b) to (5b) shown below. An anion represented by formula (4b) below is preferred.

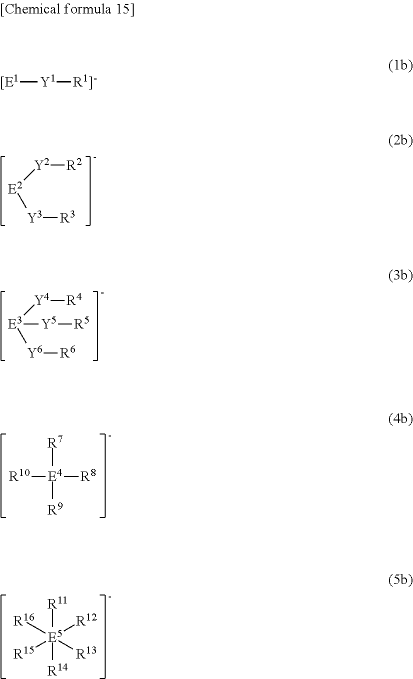

E¹ represents an oxygen atom, E² represents a nitrogen atom, E³ represents a carbon atom, E⁴ represents a boron atom or a gallium atom, and E⁵ represents a phosphorus atom or an antimony atom,

each of Y¹ to Y⁶ independently represents a single bond or a divalent linking group,

each of R¹ to R¹⁶ independently represents an electron-withdrawing monovalent group, wherein R² and R³, at least two groups selected from among R⁴ to R⁶, at least two groups selected from among R⁷ to R¹⁰, and at least two groups selected from among R¹¹ to R¹⁶, may each be bonded together to form a ring.

Each of R¹ to R¹⁶ independently represents an electron-withdrawing monovalent group. An electron-withdrawing monovalent group describes a substituent which, compared with a hydrogen atom, withdraws electrons more readily from atoms bonded to the substituent. R¹ to R¹⁶ are preferably organic groups. An organic group is an atom grouping containing one or more carbon atoms. This definition of an organic group also applies below. R² and R³, at least two groups selected from among R⁴ to R⁶, at least two groups selected from among R⁷ to R¹⁰, and at least two groups selected from among R¹¹ to R¹⁶, may each be bonded together. The bonded groups may form a ring.

Specific examples of the electron-withdrawing monovalent group include halogen atoms such as a fluorine atom, chlorine atom and bromine atom; a cyano group; a thiocyano group; a nitro group; alkylsulfonyl groups (for example, having 1 to 12 carbon atoms, and preferably 1 to 6 carbon atoms) such as a mesyl group; arylsulfonyl groups (for example, having 6 to 18 carbon atoms, and preferably 6 to 12 carbon atoms) such as a tosyl group; alkyloxysulfonyl groups (for example, having 1 to 12 carbon atoms, and preferably 1 to 6 carbon atoms) such as a methoxysulfonyl group; aryloxysulfonyl groups (for example, having 6 to 18 carbon atoms, and preferably 6 to 12 carbon atoms) such as a phenoxysulfonyl group; acyl groups (for example, having 1 to 12 carbon atoms, and preferably 1 to 6 carbon atoms) such as a formyl group, acetyl group and benzoyl group; acyloxy groups (for example, having 1 to 20 carbon atoms, and preferably 1 to 6 carbon atoms) such as a formyloxy group and an acetoxy group; alkoxycarbonyl groups (for example, having 2 to 10 carbon atoms, and preferably 2 to 7 carbon atoms) such as a methoxycarbonyl group and an ethoxycarbonyl group; aryloxycarbonyl groups or heteroaryloxycarbonyl groups (for example, having 4 to 25 carbon atoms, and preferably 5 to 15 carbon atoms) such as a phenoxycarbonyl group and a pyridyloxycarbonyl group; haloalkyl groups, haloalkenyl groups and haloalkynyl groups (for example, having 1 to 10 carbon atoms, and preferably 1 to 6 carbon atoms) in which a linear, branched or cyclic alkyl group, alkenyl group or alkynyl group has been substituted with one or more halogen atoms, such as a trifluoromethyl group and a pentafluoroethyl group; haloaryl groups (for example, having 6 to 20 carbon atoms, and preferably 6 to 12 carbon atoms) in which an aryl group has been substituted with one or more halogen atoms, such as a pentafluorophenyl group; and haloarylalkyl groups (for example, having 7 to 19 carbon atoms, and 7 to 13 carbon atoms) in which an arylalkyl group has been substituted with one or more halogen atoms, such as a pentafluorophenylmethyl group.

The aryl group and heteroaryl group are as described above in relation to R^{a} to R^{c}

Moreover, from the viewpoint of enabling efficient delocalization of the negative charge, examples of preferred electron-withdrawing monovalent groups include groups in which some or all of the hydrogen atoms of an “organic group having hydrogen atoms”, selected from among the examples of electron-withdrawing monovalent groups mentioned above, have each been substituted with a halogen atom. Specific examples of such groups include perfluoroalkylsulfonyl groups, perfluoroarylsulfonyl groups, perfluoroalkyloxysulfonyl groups, perfluoroaryloxysulfonyl groups, perfluoroacyl groups, perfluoroacyloxy groups, perfluoroalkoxycarbonyl groups, perfluoroaryloxycarbonyl groups, perfluoroalkyl groups, perfluoroalkenyl groups, perfluoroalkynyl groups, perfluoroaryl groups, and perfluoroarylalkyl groups.

Examples of particularly preferred electron-withdrawing monovalent groups include linear or branched perfluoroalkyl groups of 1 to 8 carbon atoms, cyclic perfluoroalkyl groups of 3 to 6 carbon atoms, and perfluoroaryl groups of 6 to 18 carbon atoms.

The electron-withdrawing monovalent group is not limited to the groups described above. The examples of the electron-withdrawing monovalent group mentioned above may further include a substituent or a hetero atom.

Specific examples of the electron-withdrawing monovalent group include the groups of a substituent series shown below.

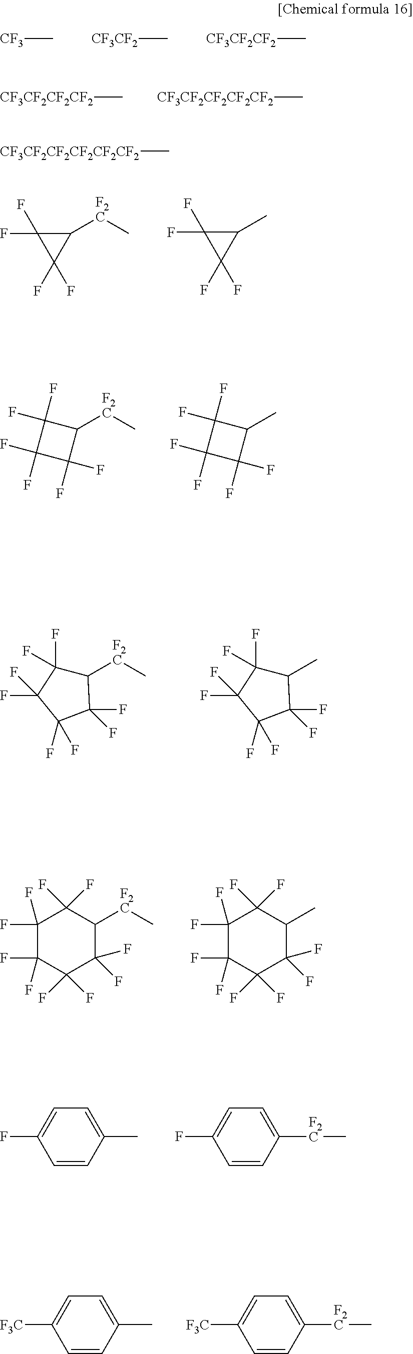

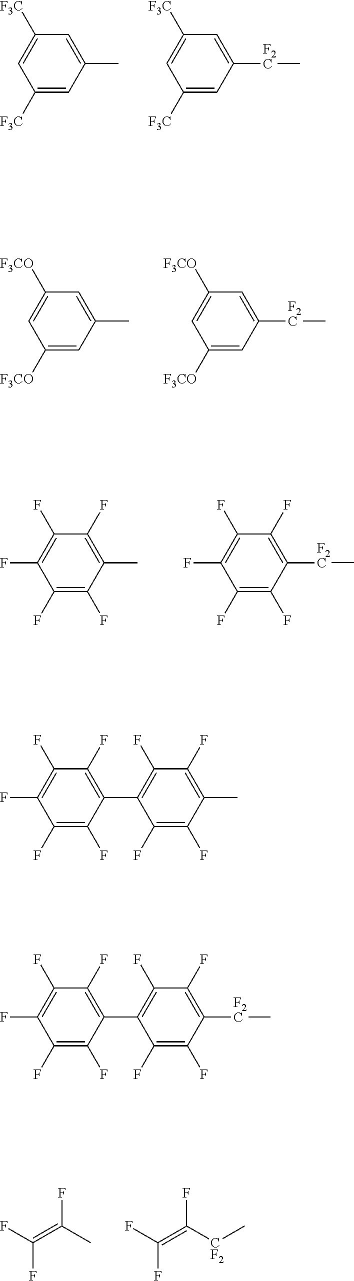

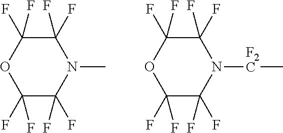

Next, each of Y¹ to Y⁶ independently represents a single bond or a divalent linking group. The cases where Y¹ to Y⁶ represent single bonds describe those cases where E and R are bonded together directly. Examples of the divalent linking group include groups represented by any one of formulas (1c) to (11c) shown below.

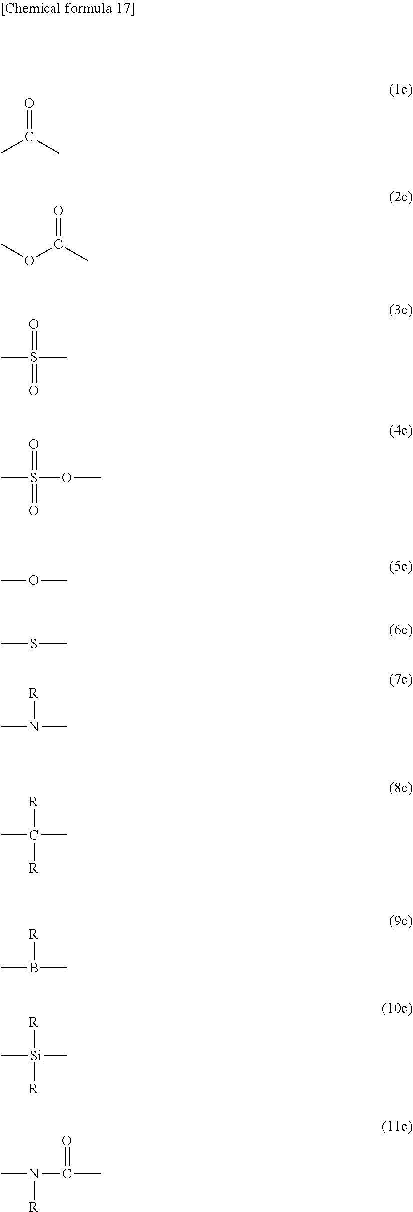

Each R independently represents a hydrogen atom or a monovalent group.

R is preferably an organic group. From the viewpoints of enhancing the electron-accepting properties and improving the solubility in solvents and the like, each R preferably independently represents an alkyl group, alkenyl group, alkynyl group, aryl group or heteroaryl group. These groups may have a substituent, and may include a hetero atom. Further, R is preferably an electron-withdrawing monovalent group, and examples of the electron-withdrawing monovalent group include the examples of electron-withdrawing monovalent groups mentioned above, and the groups shown in the above substituent series.

The anion is preferably an anion in which the negative charge resides mainly on an oxygen atom, nitrogen atom, carbon atom, boron atom or gallium atom, and is more preferably an anion in which the negative charge resides mainly on an oxygen atom, nitrogen atom, carbon atom or boron atom. Specific examples include anions represented by formulas (6b) to (9b). An anion in which the negative charge resides mainly on a boron atom is particularly desirable.

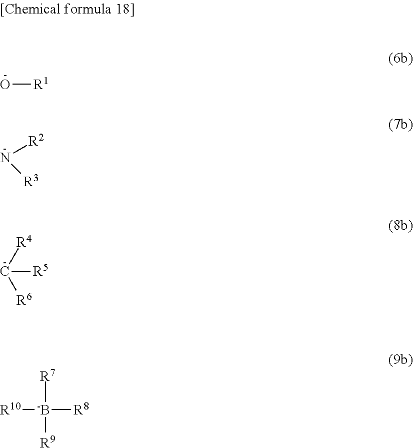

Each of R¹ to R¹⁰ independently represents an electron-withdrawing monovalent group (wherein R² and R³, at least two groups selected from among R⁴ to R⁶, and at least two groups selected from among R⁷ to R¹⁰, may each be bonded together).

R¹ to R¹⁰ are preferably organic groups. Examples of the electron-withdrawing monovalent group include the examples of electron-withdrawing monovalent groups mentioned above and the groups shown in the above substituent series, and for example, a group from the above substituent series is preferred. A group containing a perfluoroaryl group is particularly desirable.

### [Other Optional Components]

The charge transport material may also contain a dopant, a charge transport low-molecular weight compound, or another charge transport polymer or the like.

### (Dopant)

The charge transport material may include a dopant. There are no particular limitations on the dopant, provided a doping effect is achieved by adding the dopant to the hole transport polymer, enabling an improvement in the positive hole transport properties. A single type of dopant may be used alone, or a mixture of a plurality of dopant types may be used. The proton donor described above may also function as a dopant.

The dopant used in the hole transport polymer is preferably an electron-accepting compounds, and examples include Lewis acids, protonic acids, transition metal compounds, ionic compounds, halogen compounds and π-conjugated compounds. Specific examples include Lewis acids such as FeCl₃, PF₅, AsF₅, SbF₅, BF₅, BCl₃ and BBr₃; protonic acids, including inorganic acids such as HF, HCl, HBr, HNO₅, H₂SO₄ and HClO₄, and organic acids such as benzenesulfonic acid, p-toluenesulfonic acid, dodecylbenzenesulfonic acid, polyvinylsulfonic acid, methanesulfonic acid, trifluoromethanesulfonic acid, trifluoroacetic acid, 1-butanesulfonic acid, vinylphenylsulfonic acid and camphorsulfonic acid; transition metal compounds such as FeOCl, TiCl₄, ZrCl₄, HfCl₄, NbF₅, AlCl₃, NbCl₅, TaCl₅ and MoF₅; ionic compounds, including salts containing a perfluoro anion such as a tetrakis(pentafluorophenyl)borate ion, tris(trifluoromethanesulfonyl)methide ion, bis(trifluoromethanesulfonyl)imide ion, hexafluoroantimonate ion, AsF₆⁻ (hexafluoroarsenate ion), BF₄⁻ (tetrafluoroborate ion) or PF₆⁻ (hexafluorophosphate ion), and salts having a conjugate base of an aforementioned protonic acid as an anion; halogen compounds such as Cl₂, Br₂, I₂, ICl, ICl₃, IBr and IF; and π-conjugated compounds such as TCNE (tetracyanoethylene) and TCNQ (tetracyanoquinodimethane). Further, the electron-accepting compounds disclosed in JP 2000-36390 A, JP 2005-75948 A, and JP 2003-213002 A and the like can also be used. Lewis acids, ionic compounds, and π-conjugated compounds and the like are preferred.

### [Contents]

From the viewpoint of obtaining favorable hole transport properties, the amount of the hole transport polymer having a substituent represented by formula (Ia), relative to the total mass of the charge transport material, is preferably at least 50% by mass, more preferably at least 70% by mass, and even more preferably 80% by mass or greater. From the viewpoint of ensuring a satisfactory change in the degree of solubility, and from the viewpoint of enhancing the hole transport properties, the amount of the hole transport polymer having a substituent represented by formula (Ia), relative to the total mass of the charge transport material, is preferably not more than 99.99% by mass, more preferably not more than 99.9% by mass, and even more preferably 99.5% by mass or less.

From the viewpoint of ensuring a satisfactory change in the degree of solubility, and from the viewpoint of improving the hole transport properties, the amount of the proton donor, relative to the mass of the hole transport polymer, is preferably at least 0.01% by mass, more preferably at least 0.1% by mass, and even more preferably 0.5% by mass or greater. From the viewpoint of maintaining favorable film formability, the amount of the proton donor relative to the mass of the hole transport polymer is preferably not more than 50% by mass, more preferably not more than 30% by mass, and even more preferably 20% by mass or less.

### [Method for Changing Degree of Solubility]

The elimination reaction of the atom grouping (A) is initiated by heat or light irradiation or the like, but from the viewpoint of process simplicity, heating is preferred. There are no particular limitations on the heating temperature and heating time, provided the elimination reaction is able to proceed satisfactorily. A combination of both heating and light irradiation may also be performed.

A heating device such as a hot plate or oven may be used for the heating. In terms of temperature, from the viewpoint of applicability to various substrates, the temperature is preferably not more than 300° C., more preferably not more than 250° C., and even more preferably 230° C. or lower. Further, from the viewpoint of accelerating the elimination reaction, the temperature is preferably at least 40° C., more preferably at least 100° C., and even more preferably 150° C. or higher. From the viewpoint of improving productivity, the heating time is preferably not more than 2 hours, more preferably not more than 1 hour, and even more preferably 30 minutes or shorter. Further, from the viewpoint of ensuring that the elimination reaction proceeds to completion, the time is preferably at least one minute, more preferably at least 3 minutes, and even more preferably 5 minutes or longer.

For the light irradiation, a light source such as a low-pressure mercury lamp, medium-pressure mercury lamp, high-pressure mercury lamp, ultra-high-pressure mercury lamp, metal halide lamp, xenon lamp, fluorescent lamp, light emitting diode, or sunlight may be used.

### <Ink Composition>

According to one embodiment, an ink composition contains the charge transport material described above and an organic solvent capable of dissolving or dispersing the charge transport material. By using the ink composition, an organic layer can be formed easily using a simple coating method.

### (Organic Solvent)

There are no particular limitations on the organic solvent, and for example, solvents typically used when applying polymers may be used. Examples of the organic solvent include aliphatic alcohols, aliphatic hydrocarbons, aromatic hydrocarbons, aliphatic ethers, aromatic ethers, aliphatic esters, aromatic esters, amides, sulfoxides, ketones, and organic halogen compounds.

The aliphatic alcohols are preferably alcohols of 1 to 6 carbon atoms, and examples include methanol, ethanol and isopropyl alcohol.

The aliphatic hydrocarbons are preferably alkanes of 5 to 10 carbon atoms or cycloalkanes of 5 to 10 carbon atoms, and examples include pentane, hexane, octane and cyclohexane.

The aromatic hydrocarbons are preferably aromatic hydrocarbons of 6 to 13 carbon atoms, and examples include benzene, toluene, xylene, mesitylene, tetralin and diphenylmethane.

Examples of the aliphatic ethers include ethylene glycol dimethyl ether, ethylene glycol diethyl ether, and propylene glycol-1-monomethyl ether acetate.

Examples of the aromatic ethers include 1,2-dimethoxybenzene, 1,3-dimethoxybenzene, anisole, phenetole, 2-methoxytoluene, 3-methoxytoluene, 4-methoxytoluene, 2,3-dimethylanisole, and 2,4-dimethylanisole.

Examples of the aliphatic esters include ethyl acetate, n-butyl acetate, ethyl lactate and n-butyl lactate.

Examples of the aromatic esters include phenyl acetate, phenyl propionate, methyl benzoate, ethyl benzoate, propyl benzoate, and n-butyl benzoate.

Examples of the amides include N,N-dimethylformamide and N.N-dimethylacetamide.

Examples of the sulfoxides include dimethyl sulfoxide and diethyl sulfoxide.

Examples of the ketones include tetrahydrofuran and acetone.

Examples of the organic halogen compounds include chloroform and methylene chloride.

### [Amount]

The amount of the organic solvent in the ink composition can be determined with due consideration of the use of the composition in various coating methods. For example, the amount of the organic solvent is preferably an amount that yields a ratio of the charge transport material relative to the organic solvent that is at least 0.1% by mass, more preferably at least 0.2% by mass, and even more preferably 0.5% by mass or greater. The amount of the organic solvent is preferably an amount that yields a ratio of the charge transport material relative to the organic solvent that is not more than 20% by mass, more preferably not more than 15% by mass, and even more preferably 10% by mass or less.

### [Additives]

The ink composition may also contain additives as optional components. Examples of these additives include polymerization inhibitors, stabilizers, thickeners, gelling agents, flame retardants, antioxidants, reduction inhibitors, oxidizing agents, reducing agents, surface modifiers, emulsifiers, antifoaming agents, dispersants and surfactants.

### <Organic Layer>

According to one embodiment, an organic layer is a layer formed using the charge transport material or the ink composition described above. Further, according to another embodiment, a method for producing an organic layer includes a step of applying the above ink composition to form a coating layer, and a step of subjecting the coating layer to a heating treatment and/or light irradiation treatment.

By using the ink composition, an organic layer can be formed favorably by a coating method. Examples of the coating method include conventional methods such as spin coating methods; casting methods; dipping methods; plate-based printing methods such as relief printing, intaglio printing, offset printing, lithographic printing, relief reversal offset printing, screen printing and gravure printing; and plateless printing methods such as inkjet methods. When the organic layer is formed by a coating method, the organic layer (coating layer) obtained following coating may be dried using a hot plate or an oven to remove the solvent.

By subjecting the organic layer (coating layer) obtained following coating to a treatment such as heating and/or light irradiation, the atom grouping (A) can be eliminated from the hole transport polymer, thereby changing the degree of solubility of the organic layer (coating layer). For example, by stacking another organic layer on top of the organic layer for which the degree of solubility has been changed, multilayering of an organic electronic element can be achieved with ease. The organic layer for which the degree of solubility has been changed contains a hole transport polymer having a group that is formed following elimination of the atom grouping (A), for example a tolyl group.

Formation of the upper layer preferably uses an ink composition containing an organic solvent. Examples of organic solvents that may be used include the organic solvents described above, and for example in those cases where the hole transport polymer contained in the lower layer had an atom grouping (A) that exhibited high affinity relative to non-polar solvents or low-polarity solvents, one of those non-polar solvents or low-polarity solvents may be used.

From the viewpoint of improving the efficiency of charge transport, the thickness of the organic layer obtained after changing the degree of solubility is preferably at least 0.1 nm, more preferably at least 1 nm, and even more preferably 3 nm or greater. Further, from the viewpoint of reducing the electrical resistance, the thickness of the organic layer is preferably not more than 300 nm, more preferably not more than 200 nm, and even more preferably 100 nm or less.

### <Organic Electronic Element>

According to one embodiment, an organic electronic element has at least the organic layer described above. Further, according to another embodiment, a method for producing an organic electronic element includes a step of applying an ink composition to form a coating layer, and a step of forming an organic layer by subjecting the coating layer to a heating treatment and/or a light irradiation treatment. Examples of the organic electronic element include an organic EL element, an organic photoelectric conversion element, and an organic transistor and the like. The organic electronic element preferably has at least a structure in which the organic layer is disposed between a pair of electrodes.

### [Organic EL Element]

According to one embodiment, an organic EL element has at least the organic layer described above. Further according to another embodiment, a method for producing am organic EL element includes a step of applying an ink composition to form a coating layer, and a step of forming an organic layer by subjecting the coating layer to a heating treatment and/or a light irradiation treatment. The organic EL element typically includes a light-emitting layer, an anode, a cathode and a substrate, and if necessary, also includes other functional layers such as a hole injection layer, electron injection layer, hole transport layer or electron transport layer. Each layer may be formed by a vapor deposition method, or by a coating method. The organic EL element preferably has the organic layer as the light-emitting layer or as another functional layer, more preferably has the organic layer as a functional layer, and even more preferably has the organic layer as at least one of a hole injection layer and a hole transport layer.

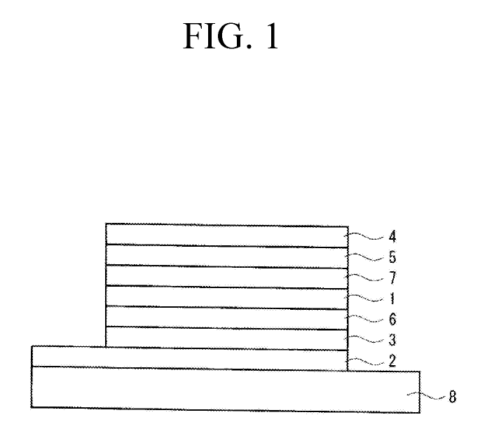

FIG. 1 is a cross-sectional schematic view illustrating one embodiment of the organic EL element. The organic EL element in FIG. 1 is an element having a multilayer structure, and includes a substrate 8, an anode 2, a hole injection layer 3 formed from an organic layer, a hole transport layer 6, a light-emitting layer 1, an electron transport layer 7, an electron injection layer 5 and a cathode 4 formed in that order. Each of these layers is described below.

### [Light-Emitting Layer]

Examples of the materials that can be used for the light-emitting layer include light-emitting materials such as low-molecular weight compounds, polymers, and dendrimers and the like. Polymers exhibit good solubility in solvents, meaning they are suitable for coating methods, and are consequently preferred. Examples of the light-emitting material include fluorescent materials, phosphorescent materials, and thermally activated delayed fluorescent materials (TADF).

Specific examples of the luminescent materials include low-molecular weight compounds such as perylene, coumarin, rubrene, quinacridone, stilbene, color laser dyes, aluminum complexes, and derivatives of these compounds; polymers such as polyfluorene, polyphenylene, polyphenylenevinylene, polyvinylcarbazole, fluorene-benzothiadiazole copolymers, fluorene-triphenylamine copolymers, and derivatives of these compounds; and mixtures of the above materials.

Examples of materials that can be used as the phosphorescent materials include metal complexes and the like containing a metal such as Ir or Pt or the like. Specific examples of Ir complexes include FIr(pic) (iridium(III) bis[(4,6-difluorophenyl)-pyridinato-N,C²]picolinate) which emits blue light, Ir(ppy)₃ (fac-tris(2-phenylpyridine)iridium) which emits green light, and (btp)₂Ir(acac) (bis[2-(2′-benzo[4,5-α]thienyl)pyridinato-N,C³]iridium(acetyl-acetonate)) and Ir(piq)₃ (tris(1-phenylisoquinoline)iridium) which emit red light. Specific examples of Pt complexes include PtOEP (2,3,7,8,12,13,17,18-octaethyl-21H,23H-porphyrin-platinum) which emits red light.

When the light-emitting layer contains a phosphorescent material, a host material is preferably also included in addition to the phosphorescent material. Low-molecular weight compounds, polymers, and dendrimers can be used as this host material. Examples of the low-molecular weight compounds include CBP (4,4′-bis(9H-carbazol-9-yl)-biphenyl), mCP (1,3-bis(9-carbazolyl)benzene), CDBP (4,4′-bis(carbazol-9-yl)-2,2′-dimethylbiphenyl), and derivatives of these compounds, whereas examples of the polymers include the organic electronic material described above, polyvinylcarbazole, polyphenylene, polyfluorene, and derivatives of these polymers.

Examples of the thermally activated delayed fluorescent materials include the compounds disclosed in Adv. Mater., 21, 4802-4906 (2009); Appl. Phys. Lett., 98, 083302 (2011); Chem. Comm., 48, 9580 (2012); Appl. Phys. Lett., 101, 093306 (2012); J. Am. Chem. Soc., 134, 14706 (2012); Chem. Comm., 48, 11392 (2012); Nature, 492, 234 (2012); Adv. Mater., 25, 3319 (2013); J. Phys. Chem. A, 117, 5607 (2013); Phys. Chem. Chem. Phys., 15, 15850 (2013); Chem. Comm., 49, 10385 (2013); and Chem. Lett., 43, 319 (2014) and the like.

### [Hole Transport Layer, Hole Injection Layer]

Examples of materials that can be used in the hole transport layer and hole injection layer include the charge transport material described above. Further, other materials that can be used in the hole injection layer and the hole transport layer include hole transport polymers that do not have a group represented by formula (Ia). With the exception of not having a group represented by formula (Ia), these hole transport polymers may have the same structure as the hole transport polymers having a group represented by formula (Ia) described above. In other words, the hole transport polymers that do not have a group represented by formula (Ia) may have, for example, a structural unit L, a structural unit T and/or a structural unit B.

Moreover, other examples of conventional materials include aromatic amine-based compounds (for example, aromatic diamines such as N,N′-di(naphthalen-1-yl)-N,N′-diphenyl-benzidine (α-NPD)), phthalocyanine-based compounds, and thiophene-based compounds (for example, thiophene-based conductive polymers (such as poly(3,4-ethylenedioxythiophene):poly(4-styrenesulfonate) (PEDOT:PSS) and the like).

### [Electron Transport Layer, Electron Injection Layer]

Examples of materials that can be used in the electron transport layer and electron injection layer include phenanthroline derivatives, bipyridine derivatives, nitro-substituted fluorene derivatives, diphenylquinone derivatives, thiopyran dioxide derivatives, condensed-ring tetracarboxylic acid anhydrides of naphthalene and perylene and the like, carbodiimides, fluorenylidenemethane derivatives, anthraquinodimethane and anthrone derivatives, oxadiazole derivatives, thiadiazole derivatives, benzimidazole derivatives, quinoxaline derivatives, and aluminum complexes. Further, the organic electronic material described above may also be used.

### [Cathode]

Examples of the cathode material include metals or metal alloys, such as Li, Ca, Mg, Al, In, Cs, Ba, Mg/Ag, LiF and CsF.

### [Anode]

Metals (for example, Au) or other materials having conductivity can be used as the anode material. Examples of the other materials include oxides (for example, ITO: indium oxide/tin oxide), and conductive polymers (for example, polythiophene-polystyrene sulfonate mixtures (PEDOT:PSS)).

### [Substrate]

Glass and plastics and the like can be used as the substrate. The substrate is preferably transparent, and a substrate having flexibility is preferred. Quartz glass and light-transmitting resin films and the like can be used particularly favorably.

Examples of the resin films include films formed using polyethylene terephthalate, polyethylene naphthalate, polyethersulfone, polyetherimide, polyetheretherketone, polyphenylene sulfide, polyarylate, polyimide, polycarbonate, cellulose triacetate or cellulose acetate propionate.

In those cases where a resin film is used, an inorganic substance such as silicon oxide or silicon nitride may be coated onto the resin film to inhibit the transmission of water vapor and oxygen and the like.

### [Emission Color]

There are no particular limitations on the emission color from the organic EL element. White organic EL elements can be used for various illumination fixtures, including domestic lighting, in-vehicle lighting, watches and liquid crystal backlights, and are consequently preferred.

The method used for forming a white organic EL element may involve using a plurality of light-emitting materials to emit a plurality of colors simultaneously, and then mixing the emitted colors to obtain a white light emission. There are no particular limitations on the combination of the plurality of emission colors, and examples include combinations that include three maximum emission wavelengths for blue, green and red, and combinations that include two maximum emission wavelengths such as blue and yellow, or yellowish green and orange. Control of the emission color can be achieved by appropriate adjustment of the types and amounts of the light-emitting materials.

### <Display Element, Illumination Device, Display Device>

According to one embodiment, a display element contains the organic EL element described above. For example, by using the organic EL element as the element corresponding with each color pixel of red, green and blue (RGB), a color display element can be obtained. Examples of the image formation method include a simple matrix in which organic EL elements arrayed in a panel are driven directly by an electrode arranged in a matrix, and an active matrix in which a thin-film transistor is positioned on, and drives, each element.

Further, according to one embodiment, an illumination device contains the organic EL element described above. Moreover, according to another embodiment, a display device contains the above illumination device and a liquid crystal element as a display unit. For example, the display device may be a device that uses the above illumination device as a backlight, and uses a conventional liquid crystal element as the display unit, namely a liquid crystal display device.

### EXAMPLES

The embodiments of the present invention are described below in further detail using a series of examples. However, the embodiments of the present invention are not limited by the following examples.

### <Synthesis of Hole Transport Polymers>

### (Preparation of Pd Catalyst)

In a glove box under a nitrogen atmosphere at room temperature, tris(dibenzylideneacetone)dipalladium (73.2 mg, 80 μmop was weighed into a sample tube, anisole (15 mL) was added, and the resulting mixture was agitated for 30 minutes. In a similar manner, tris(t-butyl)phosphine (129.6 mg, 640 μmop was weighed into a sample tube, anisole (5 mL) was added, and the resulting mixture was agitated for 5 minutes. The solutions were then mixed together and stirred for 30 minutes at room temperature to obtain a catalyst. All the solvents used were deaerated by nitrogen bubbling for at least 30 minutes prior to use.

### (Synthesis of Hole Transport Polymer 1 Containing Group Represented by Formula (Ia) at Terminals)

A three-neck round-bottom flask was charged with a monomer L shown below (5.0 mmol), a monomer B shown below (2.0 mmol), a monomer T1 shown below (4.0 mmol) and anisole (20 mL), and the prepared Pd catalyst solution (7.5 mL) was then added. After stirring for 30 minutes, a 10% aqueous solution of tetraethylammonium hydroxide (20 mL) was added. All of the solvents were deaerated by nitrogen bubbling for at least 30 minutes prior to use. The resulting mixture was heated and refluxed for 2 hours. All the operations up to this point were conducted under a stream of nitrogen.

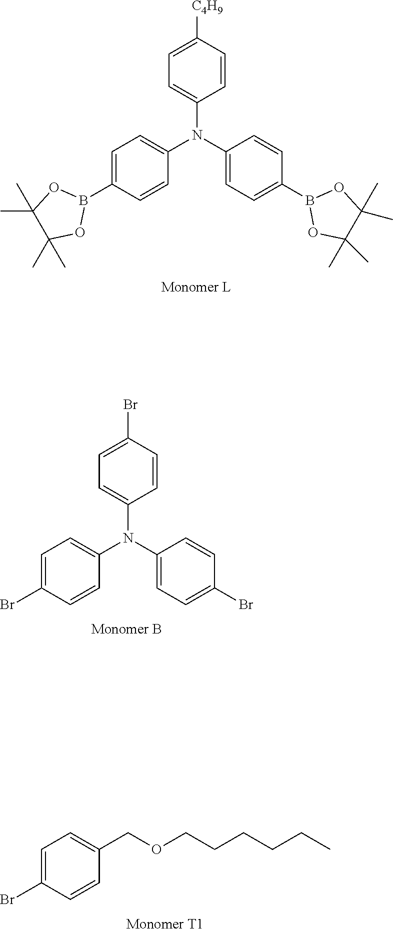

After completion of the reaction, the organic layer was washed with water, and the organic layer was then poured into methanol-water (9:1). The resulting precipitate was collected by filtration under reduced pressure, and then washed with methanol-water (9:1). The thus obtained precipitate was dissolved in toluene and re-precipitated from methanol. The thus obtained precipitate was collected by filtration under reduced pressure and then dissolved in toluene, and a metal adsorbent (“Triphenylphosphine, polymer-bound on styrene-divinylbenzene copolymer”, manufactured by Strem Chemicals Inc., 200 mg per 100 mg of the precipitate) was then added to the solution and stirred overnight. Following completion of the stirring, the metal adsorbent and other insoluble matter were removed by filtration, and the filtrate was concentrated using a rotary evaporator. The concentrate was dissolved in toluene, and then re-precipitated from methanol-acetone (8:3). The thus produced precipitate was collected by filtration under reduced pressure and washed with methanol-acetone (8:3). The resulting precipitate was then dried under vacuum to obtain a hole transport polymer 1. The obtained hole transport polymer 1 had a number average molecular weight of 15,900 and a weight average molecular weight of 41,600.

The number average molecular weight and the weight average molecular weight were measured by GPC (relative to polystyrene standards) using tetrahydrofuran (THF) as the eluent. The measurement conditions were as follows.

Feed pump: L-6050, manufactured by Hitachi High-Technologies Corporation

UV-Vis detector: L-3000, manufactured by Hitachi High-Technologies Corporation

Columns: Gelpack (a registered trademark) GL-A160S/GL-A150S, manufactured by Hitachi Chemical Co., Ltd.

Eluent: THF (for HPLC, stabilizer-free), manufactured by Wako Pure Chemical Industries, Ltd.

Flow rate: 1 mL/min

Column temperature: room temperature

Molecular weight standards: standard polystyrenes

### (Synthesis of Hole Transport Polymer 2 Containing Group Represented by Formula (Ia) at Terminals)

A three-neck round-bottom flask was charged with the monomer L shown below (5.0 mmol), the monomer B shown below (2.0 mmol), a monomer T2 shown below (4.0 mmol) and anisole (20 mL), and the prepared Pd catalyst solution (7.5 mL) was then added. Thereafter, a hole transport polymer 2 was synthesized in the same manner as the synthesis of the hole transport polymer 1. The obtained hole transport polymer 2 had a number average molecular weight of 20,200 and a weight average molecular weight of 69,000.

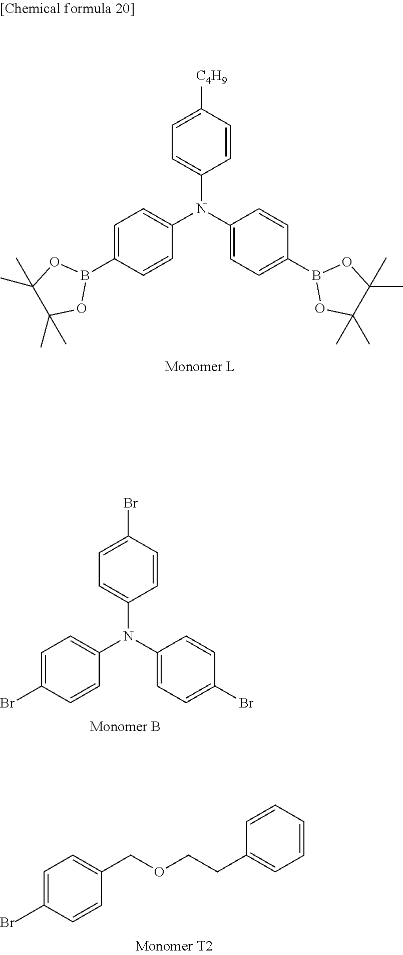

(Synthesis of Hole Transport Polymer 3 which does not Contain a Group Represented by Formula (Ia))

A three-neck round-bottom flask was charged with the monomer L shown below (5.0 mmol), the monomer B shown below (2.0 mmol), a monomer T3 shown below (4.0 mmol) and anisole (20 mL), and the prepared Pd catalyst solution (7.5 mL) was then added. Thereafter, a hole transport polymer 3 was synthesized in the same manner as the synthesis of the hole transport polymer 1. The obtained hole transport polymer 3 had a number average molecular weight of 15,800 and a weight average molecular weight of 141,100.

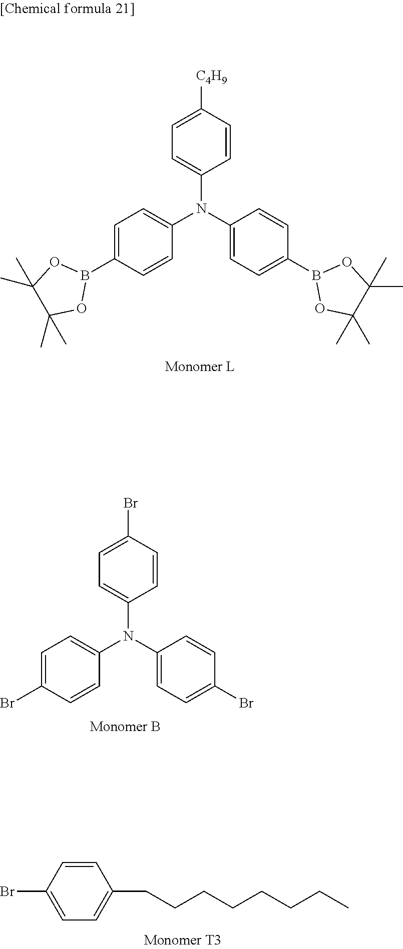

### <Evaluation of Change in Degree of Solubility of Charge Transport Materials>

### Example 1

The hole transport polymer 1 (10.0 mg) was dissolved in toluene (1,991 μL) to obtain a polymer solution. Further, an onium salt shown below (0.309 mg) was dissolved in toluene (309 μL) to obtain an onium salt solution. The thus obtained polymer solution and onium salt solution were mixed together to prepare a coating solution (an ink composition containing a charge transport material). The coating solution was spin-coated at room temperature (25° C.) at a rotational rate of 3,000 min⁻¹ onto a quartz glass plate, thus forming an organic thin film. The quartz glass plate was then heated at 180° C. for 10 minutes on a hot plate. Subsequently, the quartz glass plate was grasped with a pair of tweezers and immersed in a 200 mL beaker filled with toluene (25° C.), and the quartz glass plate was agitated 10 times back and forth in the thickness direction of the quartz glass plate over a period of 10 seconds. The absorbance (Abs) at the absorption maximum (λmax) in the UV-vis spectrum of the organic thin film was measured before and after the immersion, and the residual film ratio of the organic thin film was determined from the ratio between the absorbance values using the formula below. It can be stated that the higher the residual film ratio, the greater the change in the degree of solubility of the charge transport material.

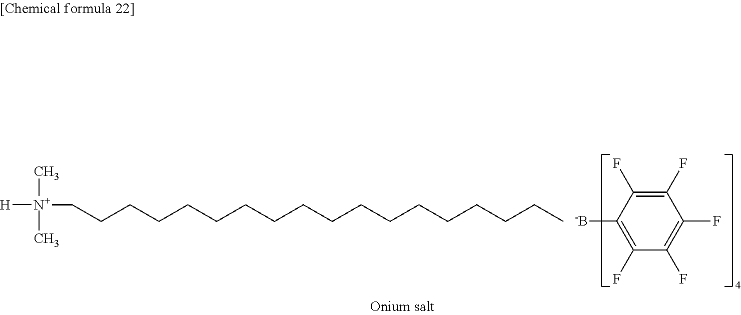

Residual film ratio (%)=Abs of organic thin film after immersion/Abs of organic thin film before immersion×100 [Numerical formula 1]

Measurement of the absorbance was performed using a spectrophotometer (U-3310, manufactured by Hitachi, Ltd.), by measuring the absorbance of the organic thin film at the maximum absorption wavelength within a wavelength range from 300 to 500 nm.

Further, with the exception of altering the heating conditions to 180° C. for 30 minutes, an evaluation of the change in the degree of solubility of the charge transport material was performed in the same manner as described above.

### Example 2

The hole transport polymer 1 (10.0 mg) was dissolved in toluene (1,189 μL) to obtain a polymer solution. Further, the onium salt shown above (1.01 mg) was dissolved in toluene (1,111 μL) to obtain an onium salt solution. The thus obtained polymer solution and onium salt solution were mixed together to prepare a coating solution (an ink composition containing a charge transport material). The coating solution was spin-coated at room temperature (25° C.) at a rotational rate of 3,000 min⁻¹ onto a quartz glass plate, thus forming an organic thin film. Thereafter, the change in the degree of solubility of the charge transport material was evaluated in the same manner as Example 1.

### Example 3

The hole transport polymer 2 (10.0 mg) was dissolved in toluene (1,991 μL) to obtain a polymer solution. Further, the onium salt shown above (0.309 mg) was dissolved in toluene (309 μL) to obtain an onium salt solution. The thus obtained polymer solution and onium salt solution were mixed together to prepare a coating solution (an ink composition containing a charge transport material). The coating solution was spin-coated at room temperature (25° C.) at a rotational rate of 3,000 min⁻¹ onto a quartz glass plate, thus forming an organic thin film. Thereafter, the change in the degree of solubility of the charge transport material was evaluated in the same manner as Example 1.

### Comparative Example 1

The hole transport polymer 1 (10.0 mg) was dissolved in toluene (2,301 μL) to obtain a polymer solution. The thus obtained polymer solution (ink composition) was spin-coated at room temperature (25° C.) at a rotational rate of 3,000 min⁻¹ onto a quartz glass plate, thus forming an organic thin film. Thereafter, the change in the degree of solubility of the hole transport polymer was evaluated in the same manner as Example 1.

### Comparative Example 2

The hole transport polymer 3 (10.0 mg) was dissolved in toluene (1,991 μL) to obtain a polymer solution. Further, the onium salt shown above (0.309 mg) was dissolved in toluene (309 μL) to obtain an onium salt solution. The thus obtained polymer solution and onium salt solution were mixed together to prepare a coating solution (an ink composition). The coating solution was spin-coated at room temperature (25° C.) at a rotational rate of 3,000 min⁻¹ onto a quartz glass plate, thus forming an organic thin film. Thereafter, the change in the degree of solubility of the charge transport material was evaluated in the same manner as Example 1.

### Comparative Example 3

The hole transport polymer 3 (10.0 mg) was dissolved in toluene (1,189 μL) to obtain a polymer solution. Further, the onium salt shown above (1.01 mg) was dissolved in toluene (1,111 μL) to obtain an onium salt solution. The thus obtained polymer solution and onium salt solution were mixed together to prepare a coating solution (an ink composition). The coating solution was spin-coated at room temperature (25° C.) at a rotational rate of 3,000 min⁻¹ onto a quartz glass plate, thus forming an organic thin film. Thereafter, the change in the degree of solubility of the charge transport material was evaluated in the same manner as Example 1.

The evaluation results for Examples 1 to 3 and Comparative Examples 1 to 3 are shown in Table 1.

TABLE 1

| | Hole | | | | |
|---|---|---|---|---|---|
| | transport | Onium | | | Residual |
| | polymer | salt | Heating | Heating | film |
| | 0.5% by | (% by | temperature | time | ratio |
| | mass *¹ | mass *²) | (° C.) | (min) | (%) |
| Example 1 | polymer 1 | 3 | 180 | 10 | 96.1 |
| | | | | 30 | 98.1 |
| Example 2 | polymer 1 | 10 | 180 | 10 | 96.4 |
| | | | | 30 | 98.3 |
| Example 3 | polymer 2 | 3 | 180 | 10 | 97.8 |
| | | | | 30 | 98.9 |
| Comparative | polymer 1 | — | 180 | 10 | 42.6 |
| Example 1 | | | | 30 | 78.7 |
| Comparative | polymer 3 | 3 | 180 | 10 | 48.4 |
| Example 2 | | | | 30 | 67.9 |
| Comparative | polymer 3 | 10 | 180 | 10 | 63.9 |
| Example 3 | | | | 30 | 77.7 |

*¹ concentration based on mass of the ink composition
*² concentration based on mass of hole transport polymer

By using a charge transport material containing a proton donor and a hole transport polymer having a group represented by formula (Ia), the degree of solubility of the hole transport polymer was able to be changed. By using the charge transport materials of Examples 1 to 3, high residual film ratios were able to be obtained. In contrast, in the case of a charge transport material that did not contain a proton donor (Comparative Example 1) and charge transport materials in which the hole transport polymer did not have a group represented by formula (Ia) (Comparative Examples 2 and 3), the results revealed low residual film ratios.

It is thought that the change in the degree of solubility of the hole transport polymers in Examples 1 to 3 is due to a cleavage reaction of the oxymethylene group derived from the monomer T1 or T2. In other words, it is thought that by mixing the proton donor with the hole transport polymer and heating the resulting mixture, the atom grouping (A) was eliminated, and the group represented by formula (Ia) was converted to a tolyl group, resulting in a change in the affinity relative to organic solvents. It is surmised that, as a result, a change occurred in the degree of solubility of the hole transport polymer in organic solvents. In Examples 1 to 3, it is thought that the degree of solubility of the hole transport polymer in toluene decreased, resulting in an increase in the residual film ratio for the organic layer.

### <Production of Organic EL Elements>

### Example 4

The hole transport polymer 1 (10.0 mg), the above onium salt (0.5 mg) and toluene (2.3 mL) were mixed together to prepare an ink composition 1. Under a nitrogen atmosphere, the ink composition 1 was spin-coated at a rotational rate of 3,000 min⁻¹ onto a glass substrate on which ITO had been patterned with a width of 1.6 mm, and the glass substrate was then heated at 210° C. for 10 minutes on a hot plate, thus forming a hole injection layer (30 nm).

Next, the hole transport polymer 3 (20.0 mg) and toluene (2.3 mL) were mixed together to prepare an ink composition 2. This ink composition 2 was spin-coated at a rotational rate of 3,000 min⁻¹ onto the above hole injection layer, and was then dried by heating at 200° C. for 10 minutes on a hot plate, thus forming a hole transport layer (40 nm). The hole transport layer was able to be formed without dissolving the hole injection layer.

Subsequently, the glass substrate was transferred into a vacuum deposition apparatus, layers of CBP:Ir(ppy)₃ (94:6, 30 nm), BAlq (10 nm), Alq₃ (30 nm), LiF (0.8 nm) and Al (100 nm) were deposited in that order using deposition methods on top of the hole transport layer, and an encapsulation treatment was then performed to complete production of an organic EL element.

### Example 5

With the exception of replacing the hole transport polymer 1 with the hole transport polymer 2, an organic EL element was produced in the same manner as Example 4.

### Comparative Example 4

With the exception of replacing the hole transport polymer 1 with the hole transport polymer 3, an organic EL element was produced in the same manner as Example 4. The hole injection layer dissolved during formation of the hole transport layer, meaning a multilayer structure could not be formed.

When a voltage was applied to the organic EL elements obtained in Example 4, Example 5 and Comparative Example 4, green light emission was confirmed in each case. For each element, the drive voltage and emission efficiency at an emission luminance of 1,000 cd/m² and the emission lifespan (luminance half-life) when the initial luminance was 3,000 cd/m² were measured. The measurement results are shown in Table 2.

TABLE 2

| | Drive | Emission | Emission |
|---|---|---|---|
| | voltage | efficiency | lifespan |
| | (V) | (cd/A) | (h) |
| Example 4 | 8 | 7 | 48 |
| Example 5 | 8 | 10 | 49 |
| Comparative | 8 | 7 | 40 |
| Example 4 | | | |

In the organic EL elements of Examples 4 and 5, by including organic layers having excellent solvent resistance, multilayer structures were able to be formed. The organic EL elements of Examples 4 and 5 exhibited longer emission lifespans than that of the organic EL element of Comparative Example 4.

Effects of the embodiments of the present invention have been illustrated above using specific examples. However, in addition to the hole transport polymers used in the examples, multilayering of organic electronic elements can be achieved using various other hole transport polymers and proton donors described above, and the resulting organic electronic elements exhibit similar superior effects.

### REFERENCE SIGNS LIST

1: Light-emitting layer
2: Anode
3: Hole injection layer
4: Cathode
5: Electron injection layer
6: Hole transport layer
7: Electron transport layer
8: Substrate

1. A charge transport material comprising a proton donor and a hole transport polymer having a group represented by formula (Ia) shown below: 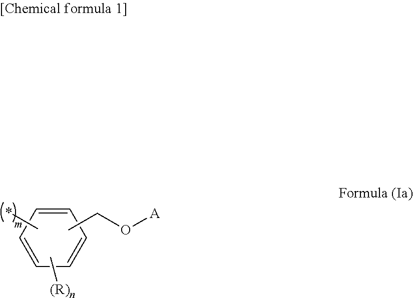
wherein A represents a monovalent organic group, each R independently represents a monovalent substituent, m represents an integer of 1 to 3, n represents an integer of 0 to 4, and m+n is 5 or less.

2. The charge transport material according to claim 1, wherein the group represented by formula (Ia) includes a group represented by formula (Ib) shown below: 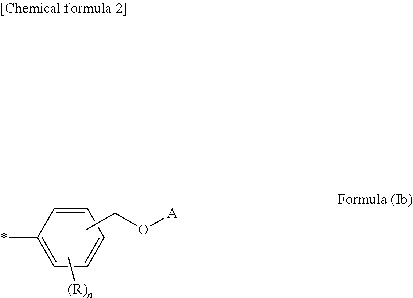
wherein A represents a monovalent organic group, each R independently represents a monovalent substituent, and n represents an integer of 0 to 4.

3. The charge transport material according to claim 1, wherein the proton donor comprises a compound represented by formula (II) shown below: 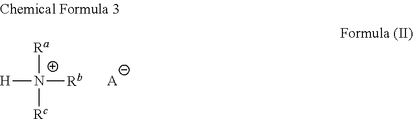
wherein:
each of R^{a} to R^{c} independently represents a hydrogen atom, an alkyl group, an arylalkyl group, an aryl group or a heteroaryl group, and at least two groups selected from among R^{a} to R^{c} may be bonded together to form a ring, and
A represents an anion.

4. The charge transport material according to claim 1, wherein the hole transport polymer has a branched structure.

5. The charge transport material according to claim 1, wherein the hole transport polymer has at least one type of structure selected from the group consisting of aromatic amine structures and carbazole structures.

6. The charge transport material according to claim 1, wherein the hole transport polymer has the group represented by formula (Ia) at least at one terminal.

7. An ink composition comprising the charge transport material according to claim 1 and a solvent.

8. An organic layer formed using the charge transport material according to claim 1.

9. An organic electronic element comprising the organic layer according to claim 8.

10. An organic electroluminescent element comprising the organic layer according to claim 8.

11. A display element comprising the organic electroluminescent element according to claim 10.

12. An illumination device comprising the organic electroluminescent element according to claim 10.

13. A display device comprising the illumination device according to claim 12, and a liquid crystal element as a display unit.

14. A method for producing an organic layer comprising a step of applying the ink composition according to claim 7 to form a coating layer, and a step of subjecting the coating layer to at least one type of treatment selected from the group consisting of heating treatments and light irradiation treatments.

15. A method for producing an organic electronic element comprising a step of applying the ink composition according to claim 7 to form a coating layer, and a step of forming an organic layer by subjecting the coating layer to at least one type of treatment selected from the group consisting of heating treatments and light irradiation treatments.

16. A method for producing an organic electroluminescent element comprising a step of applying the ink composition according to claim 7 to form a coating layer, and a step of forming an organic layer by subjecting the coating layer to at least one type of treatment selected from the group consisting of heating treatments and light irradiation treatments.
